(19) United States
(12) Patent Application Publication
(10) Pub. No.: US 2016/0111380 A1
(43) Pub. Date: Apr. 21, 2016

(54) NEW STRUCTURE OF MICROELECTRONIC PACKAGES WITH EDGE PROTECTION BY COATING

(71) Applicant: GEORGIA TECH RESEARCH CORPORATION, Atlanta, GA (US)

(72) Inventors: Venkatesh SUNDARAM, Alpharetta, GA (US); Vanessa SMET, Atlanta, GA (US); Rao R. TUMMALA, Greensboro, GA (US)

(73) Assignee: GEORGIA TECH RESEARCH CORPORATION, Atlanta, GA (US)

(21) Appl. No.: 14/919,696

(22) Filed: Oct. 21, 2015

Related U.S. Application Data
(60) Provisional application No. 62/066,609, filed on Oct. 21, 2014.

(51) Int. Cl. H01L 23/00; H01L 21/56; H01L 23/29; H01L 21/48; H01L 23/498; H01L 23/31

(52) U.S. Cl. CPC H01L 23/562; H01L 23/49827; H01L 23/49838; H01L 23/49822; H01L 23/3157; H01L 23/293; H01L 21/4846; H01L 21/56

(57) ABSTRACT

Disclosed herein are edge-coated microelectronic packages comprising a microelectronic package having a top, a bottom, and an exposed edge, and a coating comprising a polymer, wherein the microelectronic package comprises a glass substrate, and wherein the coating covers at least a portion of the top, at least a portion of the bottom, and at least a portion of the exposed edge of the microelectronic package. Also disclosed herein are methods of making and using edge-coated microelectronic packages.

### CROSS-REFERENCE TO RELATED APPLICATIONS

This application claims priority to, and the benefit under 35 U.S.C. §119(e), of U.S. Provisional Patent Application No. 62/066,609, filed 21 Oct. 2014, the entire contents and substance of which are hereby incorporated by reference as if fully set forth below.

### BACKGROUND

High coefficient of thermal expansion (CTE) organic materials (e.g., silicon) are currently the most used materials for electronic packages, but have reached their limitations in meeting emerging mobile and high-end systems performance and reliability targets. Although they are widely available, readily processable and inexpensive, they can have (1) poor dimensional stability, which can lead to coarse lithography rules and bump pitch; and (2) large CTE mismatch with the silicon chips, which can result in excessive stresses in the interconnections and in ultra-low K dielectric layers, and warpage during fabrication and assembly, which can limit assembly yield and reliability at the chip- and package-levels.

Hence, microelectronic packages made with glass materials instead of high-CTE organic materials are now being used in many applications. Microelectronic packages with glass substrates can have silicon-matched CTE and outstanding dimensional stability, which can allow for large-size packages (˜60 mm) with high-density interconnections and lithographic rules below 5 μm, and low stress on the ultra-low K dielectrics. However, glass can be more fragile and more prone to cracking during processing than the traditional high-CTE organic materials. Accordingly, improved microelectronic packages with glass substrates and improved methods of processing them are desired.

### SUMMARY

Disclosed herein are coated microelectronic packages comprising: a microelectronic package having a top, a bottom, and an exposed edge; and a coating comprising a polymer, wherein the microelectronic package comprises a glass substrate, and wherein the coating covers at least a portion of the top, at least a portion of the bottom, and at least a portion of the exposed edge of the microelectronic package.

In some embodiments, the microelectronic package further comprises a metalized or filled through package via; a blind via connecting any two conductor layers on either side of the glass substrate; a dielectric layer; a stress relief barrier layer; a metallization seed layer; a passivation layer; a conductor; or a combination thereof. In some embodiments, the glass substrate has a thickness of from 30 microns to 500 microns.

In some embodiments, the coating covers all of the exposed edge of the microelectronic package. In some embodiments, the coating has an average thickness of from 1 micron to 25 microns. In some embodiments, the coating comprises epoxy, siloxane, benzocyclobutene, polyimide, polyenzoxazole, silicone, cyanate ester, polyolefin, hydrocarbons, polyurethanes, cyanoacrylates, or a combination thereof.

In some embodiments, the coating comprises a polyepoxide and can further comprise a polyfunctional amine, acid anhydride, phenol, alcohol, thiol, or combination thereof. In some embodiments, the polyepoxide has a mean epoxide functionality of from 1 to 10.

In some embodiments, the polymer has a viscosity of 180,000 centipoises or less at 25° C. In some embodiments, the polymer has a weight average molecular weight of 400 or less. In some embodiments, the polymer has a Young's modulus of 35 GN/m² or less at 25° C. In some embodiments, the polymer has a coefficient of thermal expansion of 70×10⁻⁶ m/(m*K) or less at 25° C. In some embodiments, the coating is substantially free of fillers.

Also disclosed herein are methods of edge-coating a microelectronic package, the methods comprising: providing a microelectronic package comprising a glass substrate, wherein the microelectronic package has a top, a bottom, and an exposed edge; and coating at least a portion of the top, at least a portion of the bottom, and substantially all of the exposed edge of the microelectronic package with a coating comprising a polymer. In some embodiments, the methods further comprise curing the coating. In some embodiments, the curing comprises ultraviolet curing or thermosetting. In some embodiments, the coating covers all of the exposed edge of the microelectronic package.

Other embodiments, features, and aspects of the disclosed technology are described in detail herein and are considered a part of the claimed disclosed technology. Other embodiments, features, and aspects can be understood with reference to the following detailed description, accompanying drawings, and claims.

### BRIEF DESCRIPTION OF THE FIGURES

Reference will now be made to the accompanying figures and diagrams, which are not necessarily drawn to scale, and wherein:

FIG. 1 illustrates through package via using glass as the interposer.

FIG. 2 illustrates a stress relief barrier using glass as the interposer.

FIG. 3 illustrates a lamination system for laminating a stress relief barrier on a glass interposer.

FIGS. 4 and 5 are optical images of a side view of a stress relief barrier laminated on a glass interposer.

FIG. 6 is flow chart illustrating a method of producing a through package via.

FIG. 7 illustrates a through package via having a closed.

FIG. 8 illustrates a through package via having interlocks.

FIG. 9 is a side view of a four metal layer structure having a through package via.

FIG. 10 is a flowchart illustrating an alternate method of producing a through package via.

FIG. 11 is an example of a microelectronics package.

FIGS. 12a-e are examples of microelectronics packages showing problems caused by glass cracking after dicing.

FIG. 13a-b is an example of the tensile stress in glass that may be induced by RDL materials and processes.

FIG. 14 is a side view of a model of a microelectronics package.

FIG. 15a is an optical microscope side view of a microelectronics package.

FIG. 15b-c are side views of an example stress distribution of microelectronics package.

FIG. 16a is a side view of a PoR stackup.

FIG. 16b is a side view of a thinner stackup.

FIG. 17 is a chart showing the energy release rate required to grow cracks vs. defect size.

FIG. 18 is an example glass panel having defects resulting from the dicing process.

FIG. 19 is an example illustration of cracking in the glass that may occur due to the dicing process.

FIGS. 20a and b depict a blade diced surfaces of microelectronic packages.

FIG. 21 is a chart illustrating improvements in dicing defect size reduction.

FIGS. 22a-b show an edge with no treatment and an edge with treatment, respectively.

FIG. 23a is an example of a confocal microscopy of ablation edge.

FIG. 23b shows an optical microscope observation.

FIGS. 24a-c are examples of samples for dicing evaluation.

FIG. 24d shows a cross-sectional side view of a sample for dicing evaluation.

FIGS. 25a-d are examples of diced coupons according to various dicing conditions.

FIG. 26a is a test vehicle stack-up for a preliminary trial of glass edge coating.

FIGS. 26b-c show a top view and a side view of a coupon, respectively.

FIG. 27a-d show side image views of edge coating trials.

FIG. 28a-l show images of coupons with and without edge protection at various reflow states.

### DETAILED DESCRIPTION

Disclosed herein are methods, systems, and apparatuses related to coated microelectronic packages. Microelectronic packages with glass substrates, for instance, can have micro-defects that occur during processing (e.g., during dicing/singulation) that impact performance. For instance, before assembly, a microelectronic panel has to be singulated (singulation and dicing are used interchangeably herein) into individual functional structures. Various dicing methods exist that can be applied such as mechanical or laser dicing. The dicing processes can be adapted from wafer-level processes to minimize the damage created on the glass edges during singulation. Nonetheless, micro-defects can originate at the dicing interface from the physical dicing operation itself, or from release of the stress accumulated in the glass core during the various fabrication steps. Micro-cracks, for instance, can be created on the singulated interface and evolve into full-length cracks, propagating within the bulk of the glass core during later processing steps, such as chip-level and board-level assembly or reliability testing where heat treatments are applied to the glass structure. This phenomenon, known as SeWaRe, can considerably affect the fabrication yield of glass packages.

There are two sources of glass failure—dicing/singulation defects and stress from RDL). The occurrence of this failure mechanism can be limited by, for instance, improving glass handling during fabrication steps, optimizing of the dicing parameters, and/or optimizing the stack-up design rules to reduce residual stress in the glass core arising from copper and polymer coverage. These solutions can be highly beneficial and can improve the yield, but their application can limited by fabrication and equipment capability, as well as the needs to meet the requirements of emerging systems in terms of number of metal layers and copper coverage.

Coating the edges of the microelectronic package is a new, more systematic approach to preventing the development of SeWaRe failures from unavoidable micro-defects present in the structure. The coated microelectronic packages described herein can, in some embodiments, can address the technical challenges by coating the exposed edges of the package with a coating (which can comprise a polymer). This technology can include applying a layer of coating material on all exposed edges of glass panels, interposers or packages. The coating can be dispensed by classic underfilling dispense methods, dipping or overmolding to, for instance, coat uniformly all exposed edges of the glass in a few microns thin layer. The coating material, in some embodiments, does not contain any filler and can have a low enough viscosity to flow and fill all surface defects, even micron-size ones. Shrinkage during curing of the polymer introduces compressive stress in the structure to reduce the width of micro-cracks, and thus, in some embodiments, the shrinking of the coating during drying or curing can be minimized. After curing, the polymer can act as a stress buffer, reducing stress concentration on the singularity points where the defects were previously located, thus eliminating the risk of SeWaRe failure during post-process steps such as chip-level and board-level assembly.

Disclosed herein are microelectronic packages that are coated. The microelectronic package can be any microelectronic package known in the art. For instance, the microelectronic package can comprise an interposer/substrate; a through package via (TPV), which in some embodiments can be metalized or filled; a dielectric layer; a stress relief barrier layer; a metallization seed layer; a passivation layer; a conductor; or a combination thereof. Substrates used in semiconductor package circuits can provide a microelectronic package with a mechanical base support and an electrical interface for external communication access to the devices housed within the package.

The microelectronic package can comprise an interposer, which is an intermediate layer often used for interconnection routing between packages or integrated circuits (ICs) as a ground/power plane. Sometimes the terms “substrate” and “interposer” are used to refer to the same thing. In some embodiments, the interposer comprises glass. In some embodiments, the interposer comprises silicon. High-CTE organic materials (e.g., silicon) are currently the most used substrate materials for electronic packages, but have reached their limitations in meeting emerging mobile and high-end systems performance and reliability targets. Although they are widely available, readily processable and inexpensive, they have: (1) poor dimensional stability, leading to coarse lithography rules and bump pitch; and (2) large CTE mismatch with the silicon chips, resulting in excessive stresses in the interconnections and in ultra-low K dielectric layers, warpage during fabrication and assembly limiting assembly yield and reliability at chip- and package-levels. Interposers can include, in some embodiments, (1) good dimensional stability at ultra fine pitch; (2) good coefficient of thermal expansion (CTE) match with substrate and die, (3) good thermal path from the IC to the board; and (4) enabling of integration of embedded passive components with high quality factors.

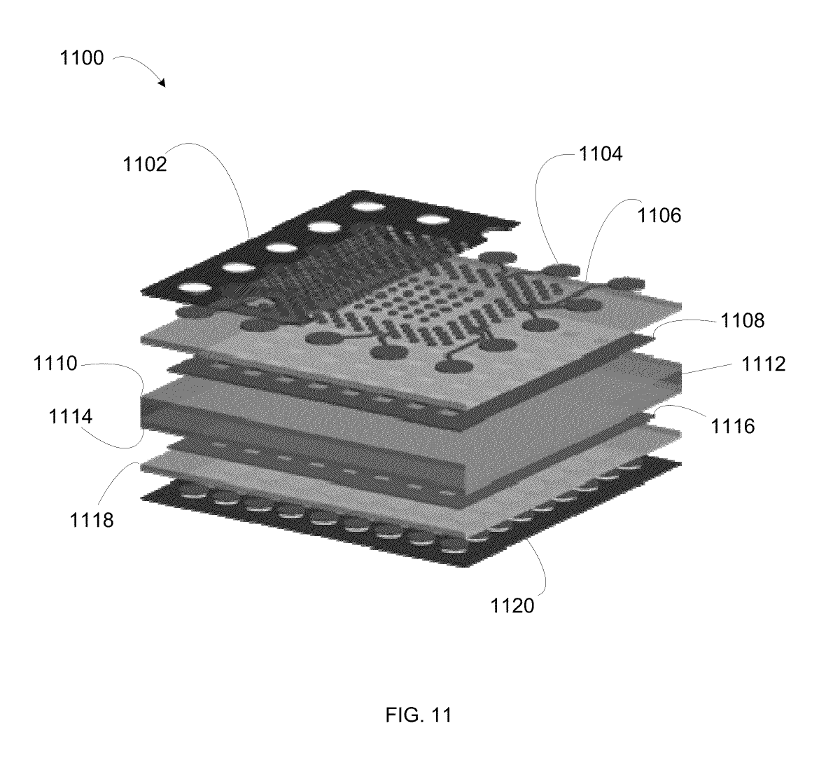

In some embodiments, the glass substrate has silicon-matched coefficient of thermal expansion. In some embodiments, the glass substrate has outstanding dimensional stability, which allows for large-size packages (˜60 mm) with high-density interconnections and lithographic rules below 5 μm, and low stress on the ultra-low K dielectrics. In some embodiments, the glass substrate and package has ultra-fine line and space (L/S) redistribution layers and metalized trough package vias using ultra-thin glass (e.g., 30-500 μm in thickness). In some embodiments, the interposer is 30 μm in thickness or greater (e.g., 50 μm or greater, 70 μm or greater, 90 μm or greater, 110 μm or greater, 130 μm or greater, 150 μm or greater, 170 μm or greater, 190 μm or greater, 210 μm or greater, 230 μm or greater, 250 μm or greater, 270 μm or greater, 290 μm or greater, 310 μm or greater, 330 μm or greater, 350 μm or greater, 370 μm or greater, 390 μm or greater, 410 μm or greater, 430 μm or greater, 450 μm or greater, 470 μm or greater, or 490 μm or greater). In some embodiments, the interposer is 300 μm in thickness or less (e.g., 50 μm or less, 70 μm or less, 90 μm or less, 110 μm or less, 130 μm or less, 150 μm or less, 170 μm or less, 190 μm or less, 210 μm or less, 230 μm or less, 250 μm or less, 270 μm or less, 290 μm or less, 310 μm or less, 330 μm or less, 350 μm or less, 370 μm or less, 390 μm or less, 410 μm or less, 430 μm or less, 450 μm or less, 470 μm or less, or 490 μm or less). The package stack-up can, in some embodiments, eventually comprises a glass substrate (i.e., glass core), several polymer dielectric build-up and metallization layers as illustrated in FIG. 11. These fabrication processes can be performed on glass panels at least 6″×6″ in size with multiple functional structures build on the same glass core.

In some embodiments, a three dimensional interposer, or 3D Interposer, can be an interconnection between multiple ICs and the circuit board, or substrate, on which the ICs are installed. When used in applications involving ICs, interposers can provide an ultra-wide bandwidth between 3D ICs by means of fine pitch through-silicon-vias (TSVs) and through-package-vias (TPVs). TSVs can be vertical electrical connections passing completely through a silicon wafer or die whereas TPVs, or generally through vias, can be vertical electrical connections passing between or passing completely through one or more packages.

TPVs can be used in the creation of 3D packages and 3D ICs. TPVs can provide the means for designers to replace the edge wiring when creating 3D packages (e.g., System in Package, Chip Stack Multi-chip Module). By using TPVs, designers of 3D packages or 3D ICs can reduce the size of the IC or package, e.g., miniaturization. This is provided for because of the reduced, or eliminated, need for edge wiring as well as the ability to double-side mount both types of active circuits, logic and memory. The use of TPVs can also help reduce the size of passives on the board. These benefits also provide a means to extend wafer level packaging to higher I/Os as an alternative to wafer level fan out technologies.

Microelectronic packages can include, for instance, a through package via stress relief barrier, or buffer layer, that can provide thermal expansion and contraction stress relief barrier along with improved metallization capabilities. The stress relief barrier can help to reduce the effects of stress caused by the different CTEs while also, in some applications, promoting adhesion between the metallization layer and the interposer. This can help to increase reliability while also providing for smaller designs.

In some embodiments, a stress buffer layer can be deposited on a glass substrate material. The stress buffer layer can be designed to also act as an adhesion promoter for the metallization layer that can be added at a later time. The stress buffer layer material can vary and can have a relatively high structural stability, exhibit low-loss properties, and can have a relatively low dielectric constant, e.g., low-k. In some instances, the stress buffer layer having one or more of these characteristics can not only help to reduce the effects of thermal stress, but the stress buffer layer can also enable high quality factor RF integration (which can be helpful in higher I/O applications). In some embodiments, the stress buffer layer can be a polymer that is applied using a vacuum heating apparatus. In some embodiments, the polymer can be a copper clad polymer.

According to some embodiments, once the stress buffer layer is deposited, through vias can be formed. Vias can be formed using various methods including, but not limited to, mechanical removal, laser ablation, or chemical removal. In some embodiments, after the vias are formed, a metallization seed layer can be applied to help promote adhesion between the via side wall and the stress buffer layer with the metallization, which is, in some embodiments, copper. In some embodiments, after the metallization is applied, selective removal of portions of the metallization occurs to produce the TPVs.

Some embodiments can involve forming one or more vias in a glass substrate. Thereafter, the vias can be filled with a polymer stress buffer layer. Holes can then be formed through the stress buffer layer. A seed layer can be formed and, thereafter, metallization can be applied. Selective removal of the metallization can form TPVs. In some embodiments, the stress buffer layer can act as the support structure for the TPVs.

In some embodiments, through vias are formed in a glass substrate material. A combined seed and buffer layer can be formed on the surface and the walls of the vias. In some embodiments, the stress/buffer layer can be a metal, such as palladium. The vias can then be filled with metallization that can be subsequently selectively removed to form TPVs.

In some embodiments, the interposer is laminated with polymer lamination. Vias can then be formed and a buffer layer can be applied to the polymer lamination and the via side walls. A combined seed layer/via fill metallization layer can be applied and then subsequently selectively removed to form TPVs.

Interposer technology has evolved from ceramic to organic materials and, most recently, to silicon. Organic substrates typically require large capture pads because they exhibit relatively poor dimensional stability. However, there are two major shortcomings seen with the present-day approach using organic substrates. It is often difficult to achieve high I/Os at fine pitch because of poor dimensional stability of organic cores. Also, warpage results as the number of layers are increased. In a lot of cases, these issues cause organic substrates, or interposers, to be particularly unsuitable for very high I/Os with fine pitch interconnections. Because of this, there has been a trend to develop and use silicon interposers instead of organic interposers. But, silicon interposers also present issues. Silicon interposers are relatively expensive to process due to the need for electrical insulation around via walls. Also, silicon interposers are limited in size by the silicon wafer from which they originate.

As an alternative to silicon, glass can be used as the interposer to address the limitations of both silicon and organic interposers. The inherent electrical properties of glass, together with large area panel size availability, can offer advantages over silicon and organic interposer materials in some applications. The use of glass, though, presents some challenges, including micro-defects and cracking during processing (e.g., dicing/singulation), the formation of vias at low cost, and glass's lower thermal conductivity when compared to silicon.

Glass is increasingly being used to solve the issues presented by conventional interposers. Glass as a substrate, e.g. interposer, has several merits. Glass has a relatively good dimensional and thermal stability, the CTE of glass is closely matched to silicon, exhibits relatively good electrical properties, and is relatively available in large panel sizes. For example, machines that process large panel liquid crystal display (LCD) glass substrates used for high definition displays can be readily incorporated for processing glass substrates, achieving low cost and higher throughput.

Table 1 compares some electrical properties, process complexity and relative cost of glass, silicon and other potential metal and ceramic interposers.

| | | CMOS grade | | | |
|---|---|---|---|---|---|
| Material | Glass | Si | Large area PV Si | Metals Cu/Al | SiC |
| Electrical Resistivity | 10¹² to 10¹⁶ | 6.4 × 10⁴ | 15 × 10⁻³ to | 1.7 × 10⁻⁶ | 10² to 10⁶ |
| (ohm · cm) | | | 40 × 10⁻³ | | |
| Electrical Insertion | Very Low | High | High | Moderate | Moderate |
| Loss | | | | | |
| Ease of via Formation | Slow | Good | Good | Moderate | Moderate |
| Ease of Metallization | Poor (direct | Dielectric liner | Dielectric liner | NA | Good |
| | deposition) | require | require | | |
| Raw Wafer or Panel | Low | High | Moderate | Low | High |
| Cost | | | | | |
| Processed Cost per I/O | Low | High | Moderate | Moderate | High |

In some embodiments a stress relief barrier, or stress relief layer, can be used to act as a buffer to absorb the stress caused by the difference of CTEs between the metal conductor (i.e., metallization, typically copper), and the glass substrate. According to some embodiments, the stress relief barrier can be an elastic interface that helps to maintain the physical connection between the metal conductor and the glass substrate, as well as any additional layers such as a metallization seed layer. The elastic property can help to reduce the probability of the occurrence of opens or shorts caused by the metal layer becoming physically detached from the interposer. Additionally, the stress relief barrier can help reduce or eliminate the propagation of cracks in the glass substrate formed either as a manufacturing defect, as a defect introduced during a processing step, or during thermal cycling. In some embodiments, using a stress relief barrier can help to reduce the thickness of the glass substrate, e.g. provide for “thin glass” interposers. Further, applying a stress relief barrier prior to via creation can help increase the pitch of the via, e.g. fine pitch or smaller pitch, by preventing removal of the top layer of the glass surrounding the via.

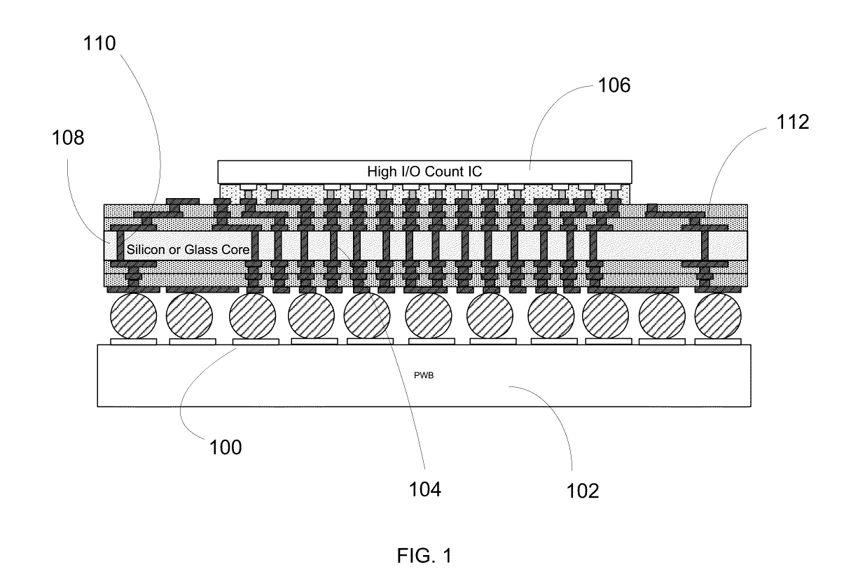

FIG. 1 illustrates a package design having through vias in a glass substrate. According to some embodiments, ball grid array 100 can be in electrical communication with printed circuit board 102. Through package vias, represented generally by through package via 104, can communicatively connect printed circuit board 102 to high I/O Count Integrated Circuit 106. Through package vias 104 can be supported by glass substrate 108. In some embodiments, stress relief barrier 112 can be deposited between copper metallization 110 and glass substrate 108 to help reduce or eliminate physical defects that can cause electrical errors such as shorts or opens caused by the different CTEs between copper 110 deposited in through vias 104 and glass substrate 108. As previously discussed, stress relief barrier 112 can be an elastic interface that helps to absorb some of the stress caused by the different CTEs to maintain copper 110 in physical contact with interposer 108.

Because stress relief barrier 112 is designed to have some elastic and insulating properties, in some embodiments, a polymer having those properties can be used. Some embodiments of polymers that can be suitable include, but are not limited to, ZIF, RXP4, Dupont™ Kapton® polymide film, Dupont™ Pyralux® AC, and Dupont™ Pyralux® AP. It should be appreciated by those of ordinary skill in the art that the present disclosure is not limited to these polymers, but can also include other suitable polymers having similar physical and electrical qualities. In some embodiments, the polymer is deposited as a dry film, liquid coating or vapor phase deposition thin film In some embodiments, stress relief barrier as a coefficient of thermal expansion between glass and the metallization. Additionally, it should be understood by those of ordinary skill in the art that the present disclosure is not limited to polymers, as other non-polymeric materials having similar physical and electrical properties can be used. In some embodiments, the metallization layer and the stress relief barrier are the same materials. In one embodiment, the metallization layer and the stress relief barrier can various metals or composite materials such as, but not limited to, copper, palladium, nickel, nickel alloys, and copper alloys.

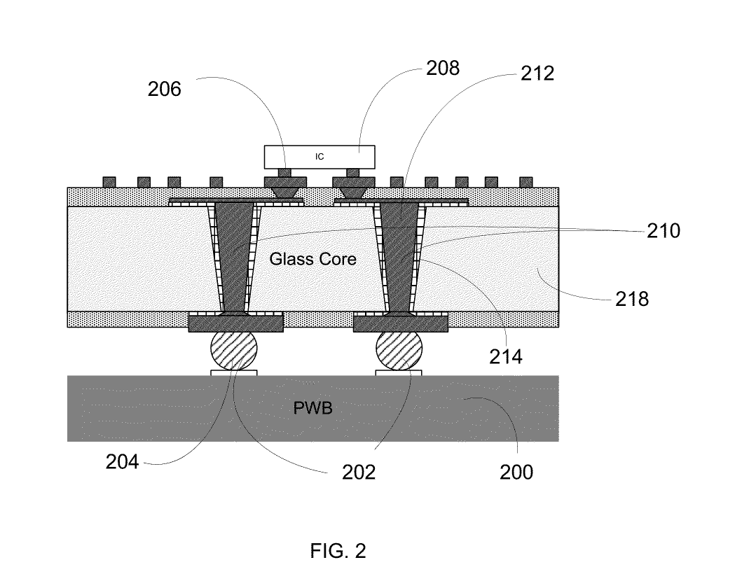

FIG. 2 is an illustration of an expanded view of a stress relief barrier. Ball grid array 202 can be on printed circuit board 200. Ball grid array 202 provides an electric communication path between communication line 204 of printed circuit board 200 and communication line 206 of integrated circuit 208. Ball grid array 202 can be in electrical communication with integrated circuit 208 through vias 210. Metal layer 212, typically copper, can provide the electrical communication pathway from ball grid array 202 to integrated circuit 208.

Metal layer 212 can expand and contract during the use of integrated circuit 208. The expansion can be caused by the heat generated when an electrical current passes through a conductor. In large scale applications, such as the wiring in a home, this heat can dissipate into the air. In small scale applications, such as microscale packaging designs, the heat cannot dissipate fast enough to prevent warming of the components in the package. This warming effect can cause the components in the package, including metal layer 212 and interposer 218, to expand. Upon the abatement of the current flow through metal layer 212, the materials can cool and contract. Interposer 218, glass in this example, can expand and contract at a different rate than metal layer 212, which typically expands faster than the interposer 218. The physical effects of this expansion and contraction, if not accounted for, can cause metal layer 212 to become partially or wholly removed from either glass substrate 218, ball grid array 202, or integrated circuit 208, or all of them.

To reduce the effects of the stress cause by the thermal cycling, stress relief barrier 214 can be deposited between one or more portions of the metal layer 212 and glass substrate 218. As metal layer 212 and glass substrate 218 expand and contract, stress relief barrier 214, in some embodiments an elastic or semi-elastic polymer, can absorb the stress developed between metal layer 212 and interposer 218, maintaining the physical connection between metal layer 212 and vias 21. Stress relief barrier 214 can help to prevent the lifting or failure of vias 210, thereby maintaining electrical connectivity from printed circuit board 200 to integrated circuit 208. Additionally, depending on the type of polymer selected, stress relief barrier 214 can also promote adhesion of metal layer 212 to interposer 218 by acting as a type of “glue” that maintains the bond between interposer 218 and metal layer 212.

According to some embodiments, the stress relief barrier is between the metal layer on the surface of the glass substrate and the metal in the core of the vias as well. In addition, the stress relief barrier can also help reduce the physical impact of a laser on the glass surface during the ablation process. In conventional systems, when a laser or other material removing means, such as acid, is used to create a through via, the top portion of the substrate can be acted upon by the removal means for a longer period of time than the lower portions. An unintended consequence of this longer reaction time can be that there is a continual removal of some of the top layers of the substrate. This can cause low pitch vias, i.e. vias having side walls angles less than normal to the plane of the substrate. Low pitch vias can not only require an increased amount of metallization to fill the via, thus increasing costs, but the dimensions of low pitch vias can reduce the number of through vias that can be placed in an area on the substrate.

It is often desirable to produce through vias that have small or fine pitches. As previously discussed, a small or fine pitch means that the walls of the vias are normal or nearly normal to the plane of the surface of the substrate, e.g. vertical or nearly vertical. A through via with coarse pitch can have walls that extend in a diagonal direction from the base of the through via, forming a “V” shape. The formation of fine pitch vertical feed through on glass is a challenge while building a 3D interposer. Etching glass is typically more difficult than etching silicon. Wet etching yields higher etch rates (˜10 μm/min) but the isotropy of etch profile is unfavorable for through vias on thick substrates.

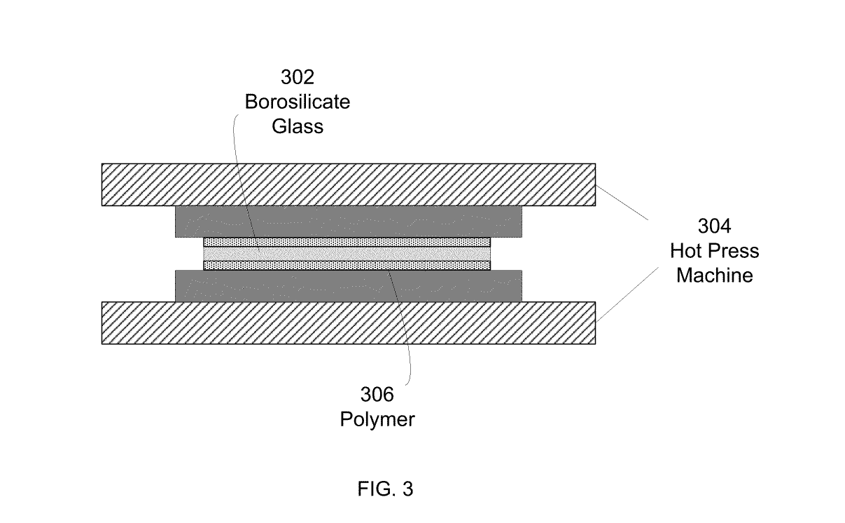

To achieve higher pitch through vias in glass, a stress relief barrier can be used as a shield or protective barrier to prevent the material removal means from undesirably removing top portions of the substrate around the through via. FIG. 3 is an illustration of a system for depositing a polymer layer on a glass substrate prior to removal of the substrate material to form a through via. Borosilicate glass (BSG) is a type of glass that can be used as an interposer. It should be understood that the present disclosure is not limited to BSG as the interposer material. The surface of glass 302 can be first treated using acetone and Isopropyl alcohol. This treatment can help to provide a clean surface for lamination.

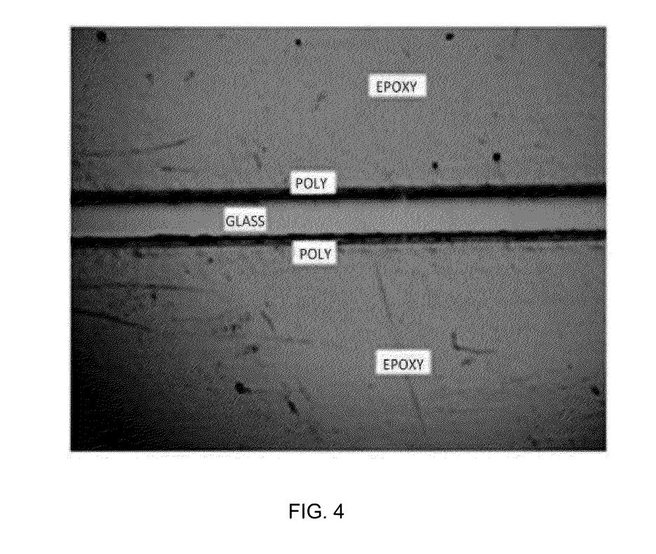

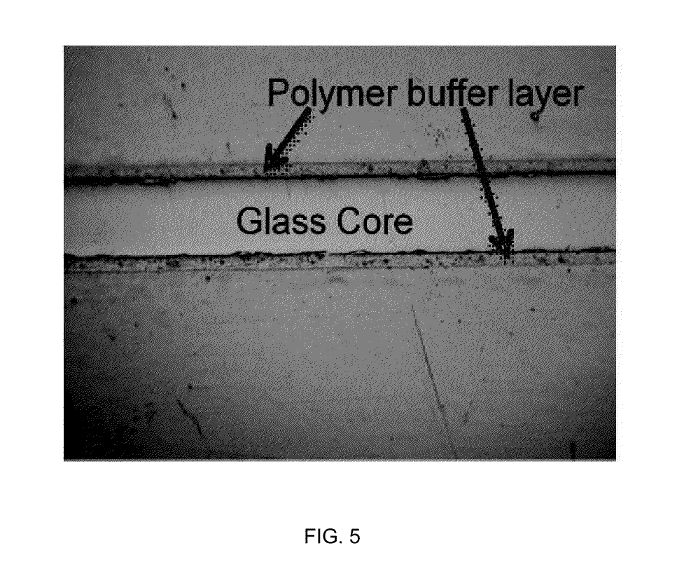

A hot press machine 304 can be used to carry out the double sided lamination of polymer 306. It should be noted that the lamination process can be used on one surface, e.g. the top surface or bottom surface of glass 302, or, on both the bottom and top surfaces. The laminated glass 302 can then be subjected to laser ablation. During the laser ablation process, polymer 306 can act as a stress relief barrier as well as a protective shield. FIGS. 4 and 5 show the optical cross-section images of polymer on glass when using a process and materials similar to the process of FIG. 3.

As discussed previously, the stress relief barrier can help to promote adhesion between the glass substrate and the metal conductor. In some embodiments it can be preferable or necessary to deposit the metal directly on the glass substrate, such as in the case of a wall of a through via. Direct Metallization on glass can be a challenge due to CTE mismatch at the metal glass interface. Surface modification techniques can enhance direct metal adhesion on glass, but fabrication of a relatively thick metal liner on glass can result in de-lamination. The use of a polymer stress relief barrier can help to promote metal adhesion on the glass surface. Typically, TPV metallization is a two step process. A seed layer can be first formed on all or part of the surfaces of the TPV which can be followed by metallization using, among other metals and methods, copper electroplating. There can be various ways to form a seed layer. For example, and not by way of limitation, electroless copper deposition or sputtering can be used to form the seed layer.

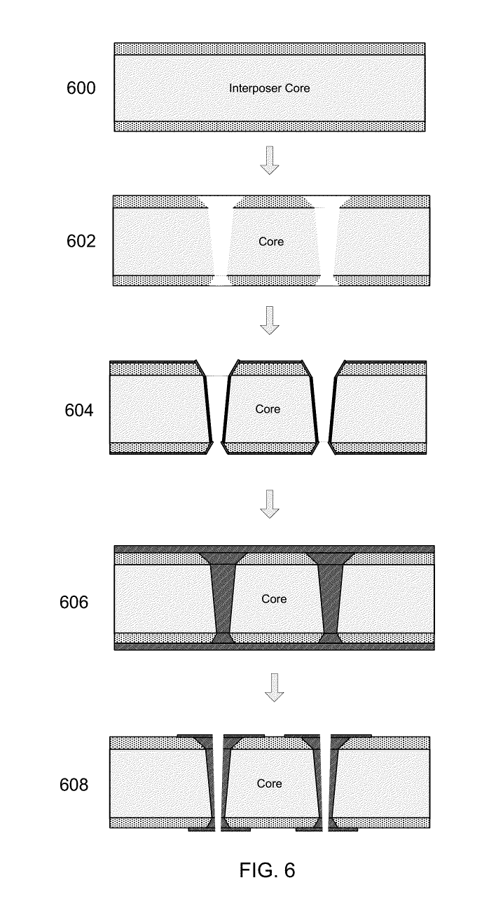

FIG. 6 is an embodiment of a method for producing through vias in a glass substrate. A polymer can be laminated 600 on at least a portion of a top surface of a glass substrate. In some embodiments, a polymer can be laminated on at least a portion of a bottom surface of the glass substrate. In another embodiment, a copper or other metal layer can be deposited on the glass surface or on the polymer lamination layer. At least of portion of the interposer and lamination are removed 602 to form a through via. A metallization seed layer can be applied 604 before plating or depositing 606 a metal layer. Thereafter, a portion of the metallization layer can be selectively removed 608 to form a metalized through package via.

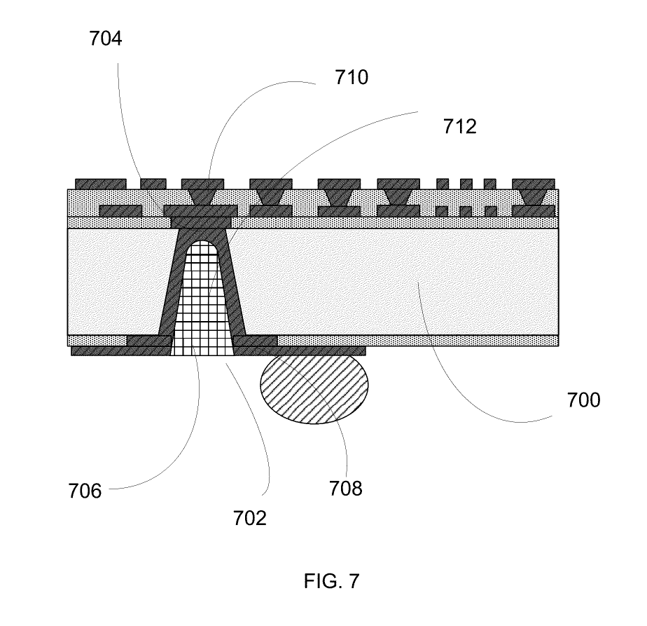

When removing the metallization seed layer and the lamination, as disclosed by way of example in FIG. 6, it can be beneficial to remove the material in such a way as to provide for other functionality or advantages. For example, FIG. 7 illustrates an embodiment of an interposer with a through via having one portion of the through via partially or fully closed off with the metallization layer. For example, and not by way of limitation, stress induced by thermal expansion and contraction can be absorbed by having one portion of a through via closed off while allowing the other portion to remain open. In FIG. 7, interposer 700, which can be manufactured from various types of media including BSG, has been ablated to remove material from interposer 700 to form through via 702. According to some embodiments, through via 702 can comprise a top portion 704 and a bottom portion 706. It should be noted that the designations of “top” and “bottom” are not intended to limit the present disclosure to any geometric or spatial configuration, but rather, are being used merely to designate two different portions for purposes of illustrating a embodiment.

As shown in FIG. 7, the metallization layer 710 on top portion 704 when deposited can be deposited in such a manner to close off top portion 704. But in this embodiment, when metallization layer 708 was deposited, the bottom portion 706 was not filled in, thus providing for one portion of through via 702, i.e. top portion 704, to be closed off while the bottom portion 706 remains open. When the interposer 700 and metallization layers 708 and 710 expand and contract due to thermal cycling, the open portion, in this illustration bottom portion 706, can act like a spring or resilient surface to absorb the expansion and contraction. In some embodiments of the present disclosure, the closed off portion on the top side can facilitate blind via stacking In some embodiments of the present disclosure, it can be advantageous or necessary to fill in the remaining portion of through via 702 with some media. In some embodiments, a filler 712 can be deposited in through via 702. Filler 712 can be various types of materials including, without limitation, a polymer or a metal alloy. If through via 702 is not filled with a media, air can act as filler 712.

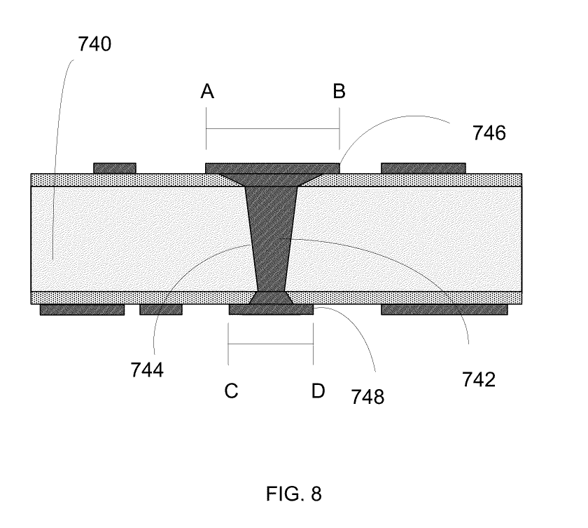

In some embodiments, additional stabilization features are provided in a through via. FIG. 8 illustrates the use of variable width metallization layers that can help to secure the metallization in the through via in an interposer. Because in some instances the use of a seed layer deposited on the walls of a through via can be impractical, thus possibly reducing the adhesion between a metallization layer and the walls of the through via, when the materials of a through via are thermally cycled, the metallization in the through via can separate from the walls of the through via. Without other physical support to keep the metallization in the through via, the metallization can lift off of the walls of the through via and the interposer, possibly creating shorts or opens in the microelectronic package.

To help maintain the metallization in the through via through periods of thermal cycling, FIG. 8 illustrates the use of interlocks. Illustrated is interposer 740 with through via 742. Through via 742 has metallization 744 deposited throughout through via 744. In some embodiments, when metallization 744 was deposited, after deposition, portions of metallization 744 were selectively removed to form top interlock 746 and bottom interlock 748. It should be noted that the designations of “top” and “bottom” are not intended to limit the present disclosure to any geometric or spatial configuration, but rather, are being used merely to designate two different portions for purposes of illustrating a embodiment.

Top interlock 746 can have an outer diameter AB whereas bottom interlock 748 can have an outer diameter CD. In some embodiments, the length of diameter AB can be longer, shorter, or the same length as diameter CD. The relationship between the lengths of diameters AB and CD can vary depending on the particular application of through via 742, costs, or other factors. Interlocks 746 and 748 secure metallization 744 in through via 742. It is intended that even if through via 742 metallization 744 separates from the side walls of through via 742, the securing action provided by top interlock 746 in combination with bottom interlock 748 can secure metallization 744 in through via 742.

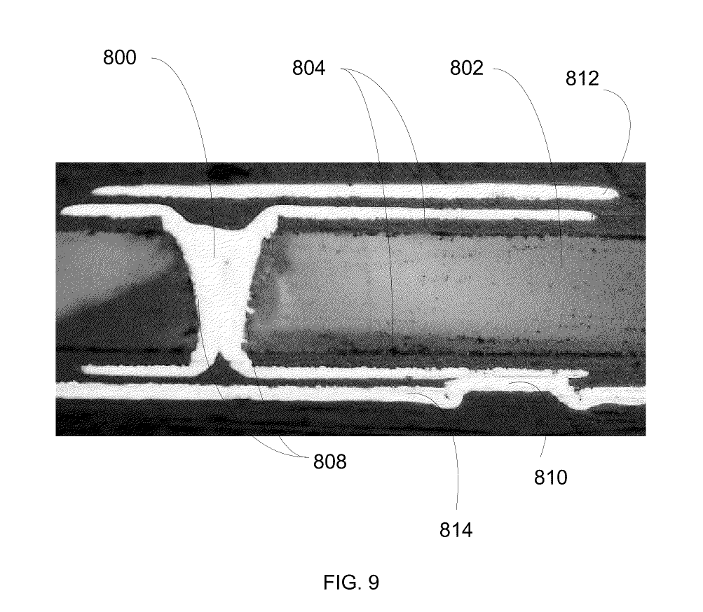

Using various securement features, such as interlocks 746 and 748 of FIG. 8 or the closed off portion 704 of FIG. 7 can provide for additional features to be built onto a through package via. For example, because the reliability of the through package vias can be increased, in some embodiments, additional polymer layer features can be built on the through package vias. FIG. 9 depicts an embodiment with a cross-section of a four-metal layer structure of a glass substrate with polymer buildup. The cross-sectional view of FIG. 9 shows a four-metal layer structure with larger via diameters (with entrance diameter of 150 μm). Via 800 on glass substrate 802 can be fabricated after depositing polymer lamination 804 on glass substrate 802. According to some embodiments, double side simultaneous process can be used to obtain patterned metallization. In some embodiments, lamination 804 cannot be deposited on the walls 806 of via 800. In some embodiments, blind staggered vias, such as via 810, can be used to connect topmost metal layer 812 with the adjacent bottom metal layer 814. Metallization on the polymer buildup can be carried out using various processes including, but not limited to, a semi-additive plating process. The use of blind vias, such as via 810, can, among other benefits, help to ease the interconnection conflicts present in high density interconnect packaging.

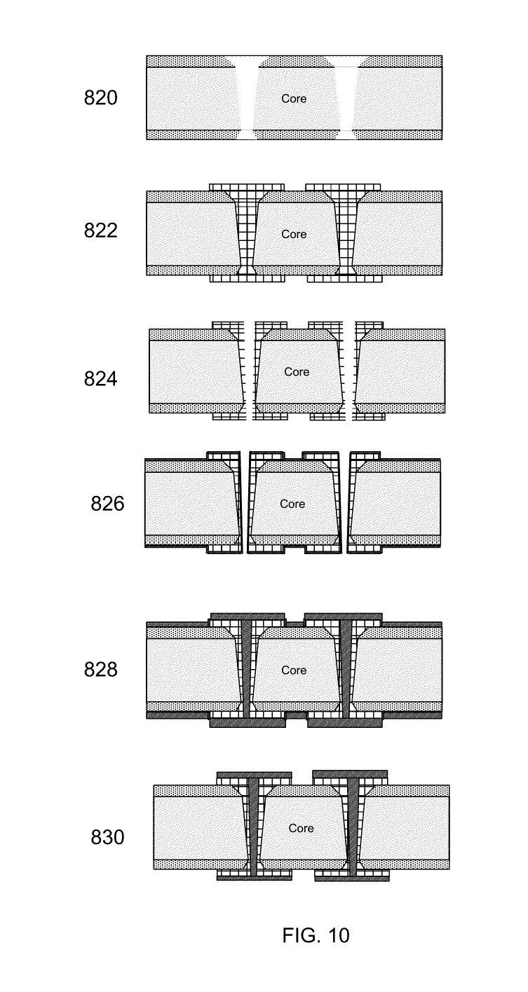

FIG. 10 is an alternate embodiment of a method to produce through package vias. A portion of a glass substrate can be removed 820 to form a through via. The through via can then be filled 822 with a stress relief barrier material such as a dielectric or polymeric material. At least a portion of the dielectric can be removed 824 to form at least one high density through via. A metallization seed layer can be applied 826 on at least a portion of the lamination layer, wherein the metallization seed layer can also fill at least a portion of at least one through hole. A metal forming the metallization layer can be deposited 828 on the seed layer. Thereafter, a portion of the metallization layer can be selectively removed 830 to form a metalized through package via. In some embodiments, the metallization layer can be removed to form interlocks.

FIG. 11 depicts one embodiment of a microelectronics package disclosed herein. FIG. 11 shows an example embodiment of a microelectronics package, which may also be referred to as a coupon. According some embodiments, a microelectronics package may be made up of a plurality of layers. For example, as shown in FIG. 11, a microelectronics package 1100 may have a first layer 1102, a second layer 1104, a third layer 1106, a fourth layer 1108, a fifth layer 1110, a sixth layer 1112, a seventh layer 1114, and an eighth layer 1116. According to some embodiments, the first layer 1102 can be a passivation dielectric having a thickness of 10 μm, the second layer 1104 may be a layer of copper having a thickness of 10 μm, the third layer 1106 may be an ILD2A polymer having a thickness of 17.5 μm, the fourth layer 1108 may be a layer of copper having a thickness of 10 μm, the fifth layer 1110 may be a low CTE glass having a thickness of 100 μm, the sixth layer 1112 may be an ILD1B polymer having a thickness of 17.5 μm, the seventh layer 1114 may be a layer of copper having a thickness of 10 μm, the eighth layer 1116 may be a ILD2B polymer having a thickness of 17.5 μm, the ninth layer 1118 may be a layer of copper having a thickness of 10 μm, and the tenth layer 1120 may be a passivation dielectric having a thickness of 10 μm. As those of skill in the art will appreciate, this is merely one example embodiment of a microelectronics package, and other embodiments of microelectronics packages can be made of more or less layers comprised of a variety of different materials and thicknesses.

The layers depicted in FIG. 11 or described herein are merely examples of layers in microelectronic packages. Those of ordinary skill in the art would recognize that additional layers could be included. Those of ordinary skill in the art would also recognize that not all layers in FIG. 11 are necessary in every microelectronics package.

The panels and packages disclosed herein undergo processing that can include dicing (aka singulation). Microelectronic packages with glass substrates, for instance, can have micro-defects that occur during processing (e.g., during dicing/singulation) that impact performance. For instance, before assembly, a microelectronic panel has to be singulated (singulation and dicing are used interchangeably herein) into individual functional structures. Various dicing methods exist that can be applied such as mechanical or laser dicing. The dicing processes can be adapted from wafer-level processes to minimize the damage created on the glass edges during singulation. Nonetheless, micro-defects can originate at the dicing interface from the physical dicing operation itself, or from release of the stress accumulated in the glass core during the various fabrication steps. Micro-cracks, for instance, can be created on the singulated interface and evolve into full-length cracks, propagating within the bulk of the glass core during later processing steps, such as chip-level and board-level assembly or reliability testing where heat treatments are applied to the glass structure. This phenomenon, known as SeWaRe, can considerably affect the fabrication yield of glass packages.

The occurrence of this failure mechanism can be limited by, for instance, improving glass handling during fabrication steps, optimizing of the dicing parameters, and/or optimizing the stack-up design rules to reduce residual stress in the glass core arising from copper and polymer coverage. These solutions can be highly beneficial and can improve the yield, but their application can limited by fabrication and equipment capability, as well as the needs to meet the requirements of emerging systems in terms of number of metal layers and copper coverage.

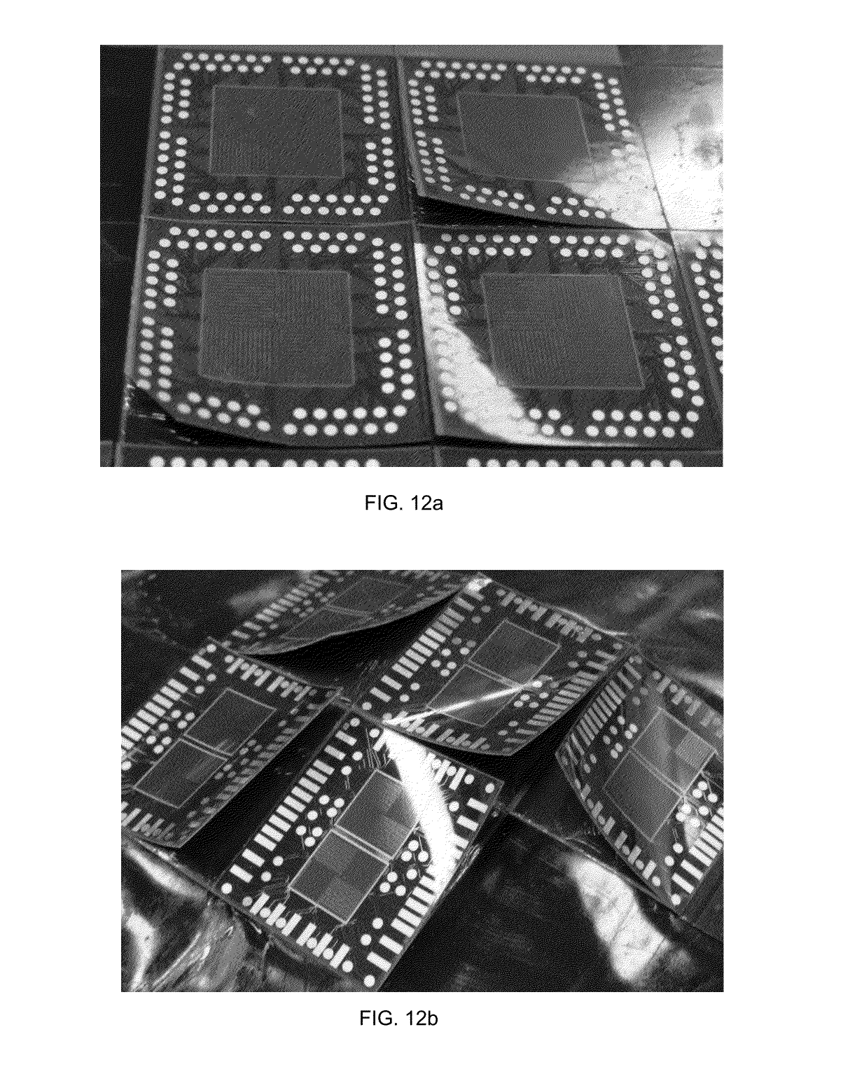

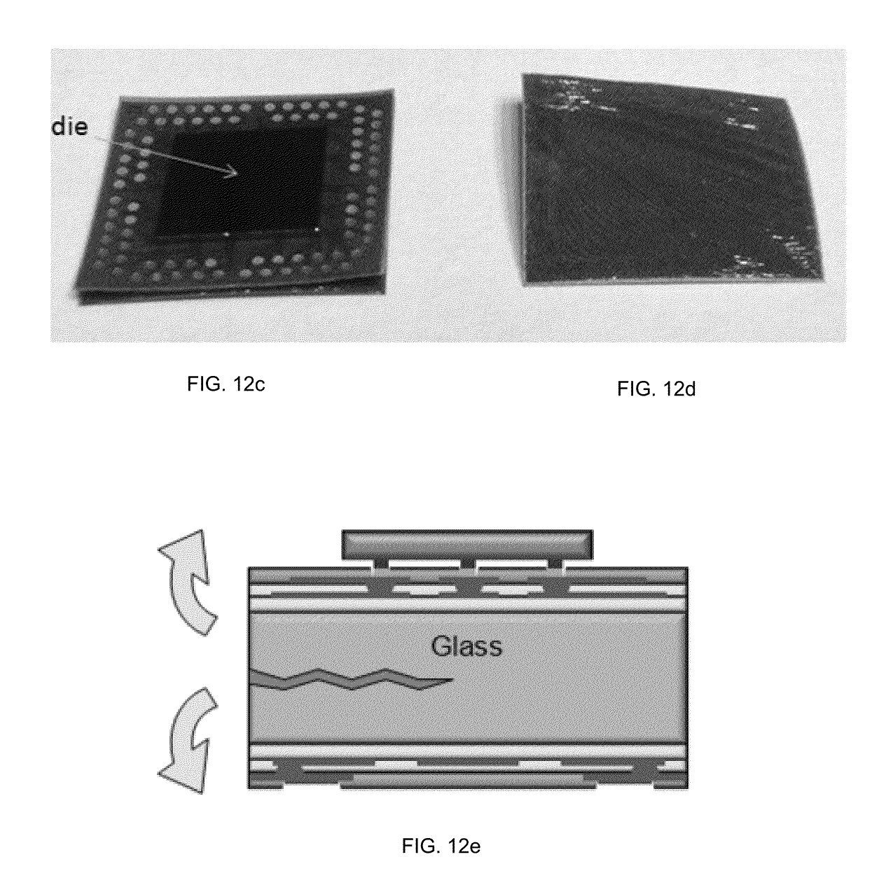

FIGS. 12a-e show the problems caused due to glass cracking (SeWaRe) after dicing a glass panel. FIG. 12a shows a 2D glass package, FIG. 12b shows a 2.5D glass substrate, FIG. 12c shows a the top part of a substrate, FIG. 12d shows a the bottom part of a substrate, and FIG. 12e shows a side view of a crack in the glass. As can be seen in FIG. 12e, a crack formed in the glass may propagate outwards causing the layers of the microelectronics package to separate and deform. Such separations and deformations are shown in FIGS. 12a-d. This phenomenon is very problematic, as such separations and deformations may cause the microelectronics package experience a degradation of performance or to fail entirely. C-SAM (scanning acoustic microscopy) can be an effective tool in inspecting defects as they grow into failures. Multiple types of defects can occur, including, for instance, larger defects (>10 microns) or chipping/smaller defects on the polymer/substrate interface. These failures can occur in many points during the lifecycle of a microelectronic package (e.g., during polymer cure, during copper plating, during soldermask/passivation cure, during dicing, during pre-conditioning, during temperature cycling, or a combination thereof). The failure can occur for a variety of causes that cause defect propagation (including moisture ingress or additional stress). Stress quantification can be measured, for instance, retardation measurements and warpage measurement on a single-sided sample. Stress reduction can be accomplished by, for instance, thinner copper layers, thinner polymer redistribution layers (RDL), and/or adjustment in the structure.

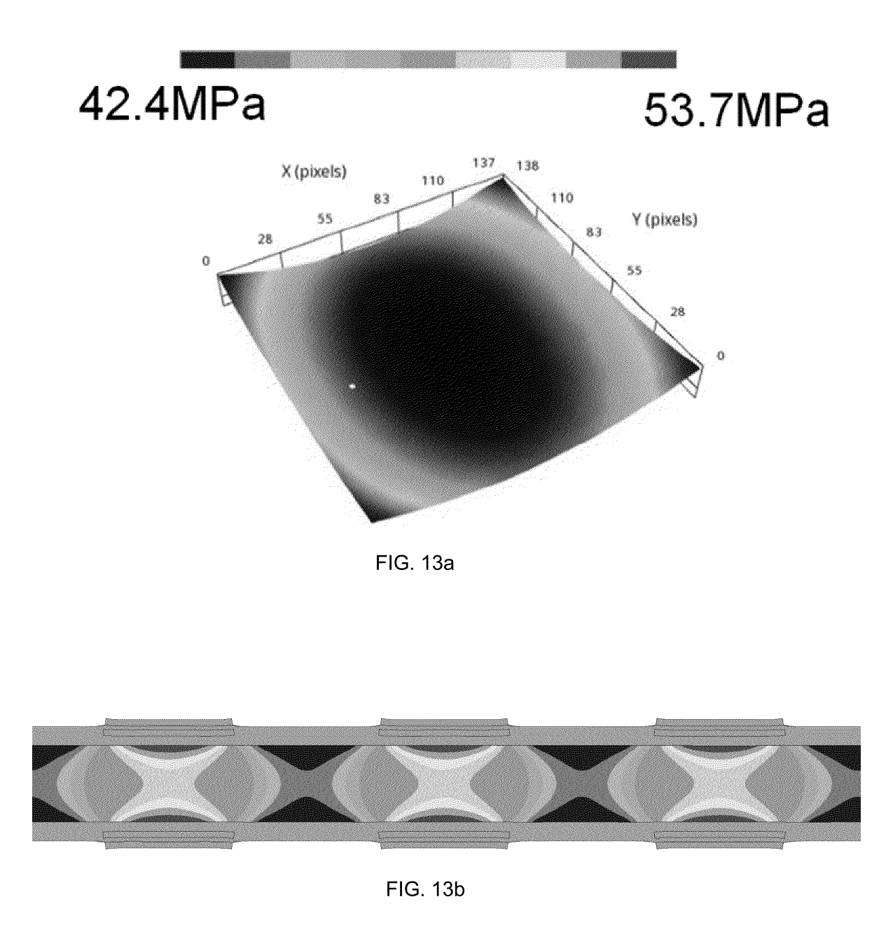

FIG. 13a shows an example of the tensile stress in glass that may be induced by RDL materials and processes. Such tensile stress may greatly contribute to failures or cracks in the glass. FIG. 13b shows the side view thereof.

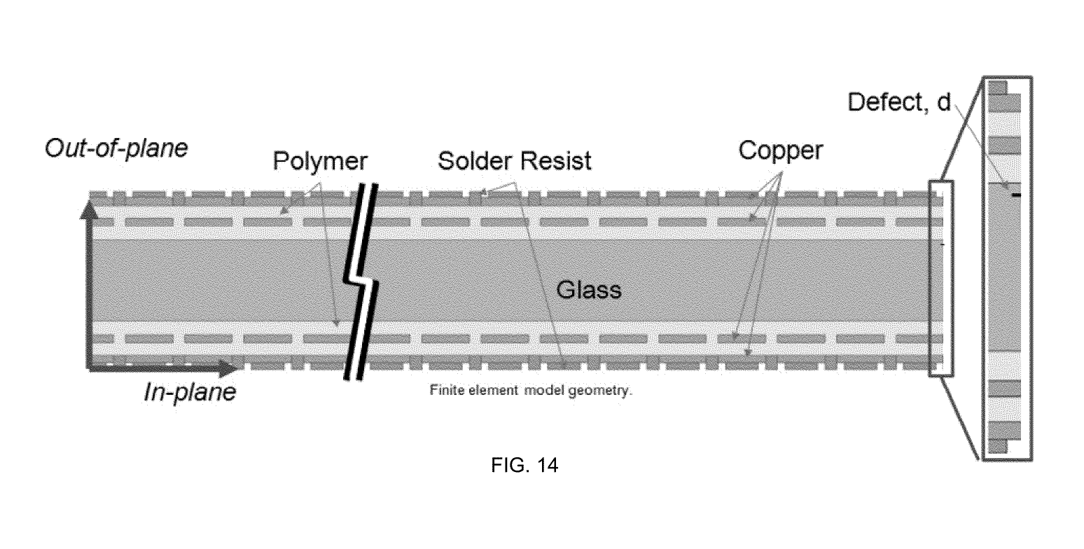

FIG. 14 shows finite element modeling considering fracture mechanics. The model depicted is built to mimic PoR structure. A 2D strain model is chosen for comparison and fracture. A defect of size d introduced at the glass edge is also depicted.

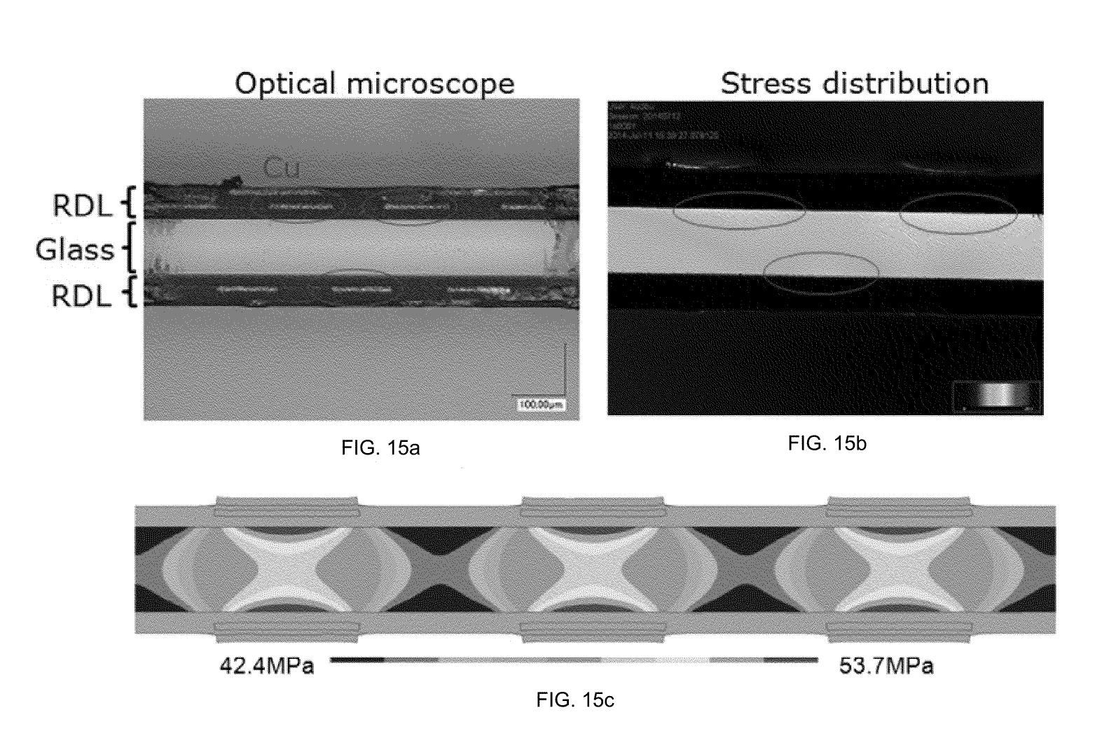

FIGS. 15a-c show model validation involving retardation stress measurement, showing the von Mises stress in the glass. The model can be validated with predicted values, for example, values estimated near 50 MPa.

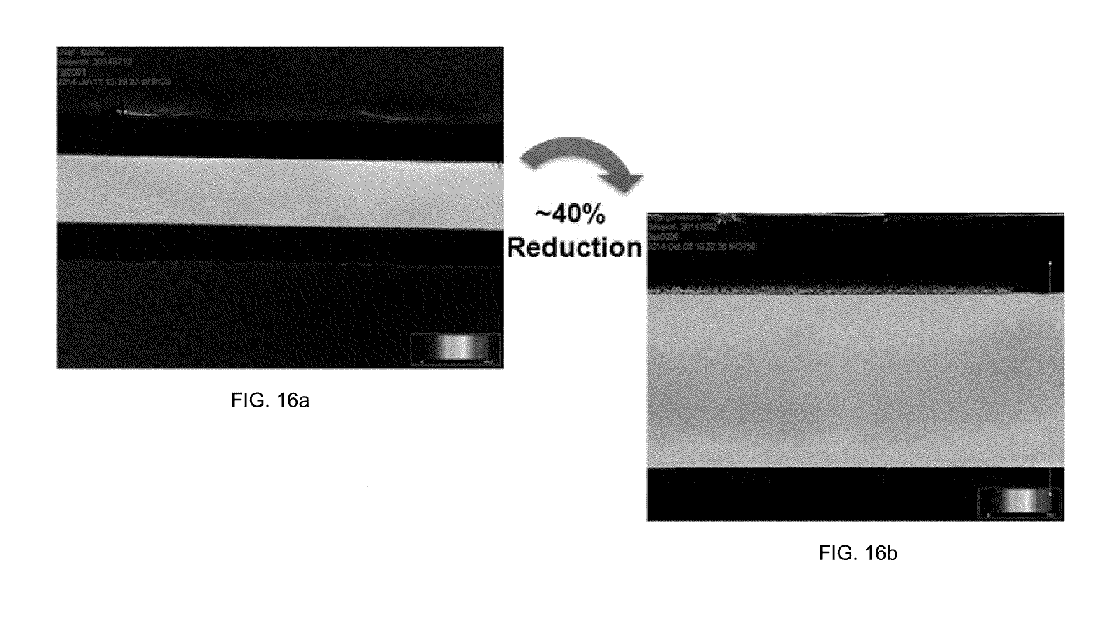

FIGS. 16a-b show that the stress can be significantly reduced by thinner RDL stacks. FIG. 16a shows a PoR stackup and FIG. 16b shows a thinner stackup. According to some embodiments, there can be an approximately 40% reduction in the RDL stack from the PoR stackup to the thinner stackup.

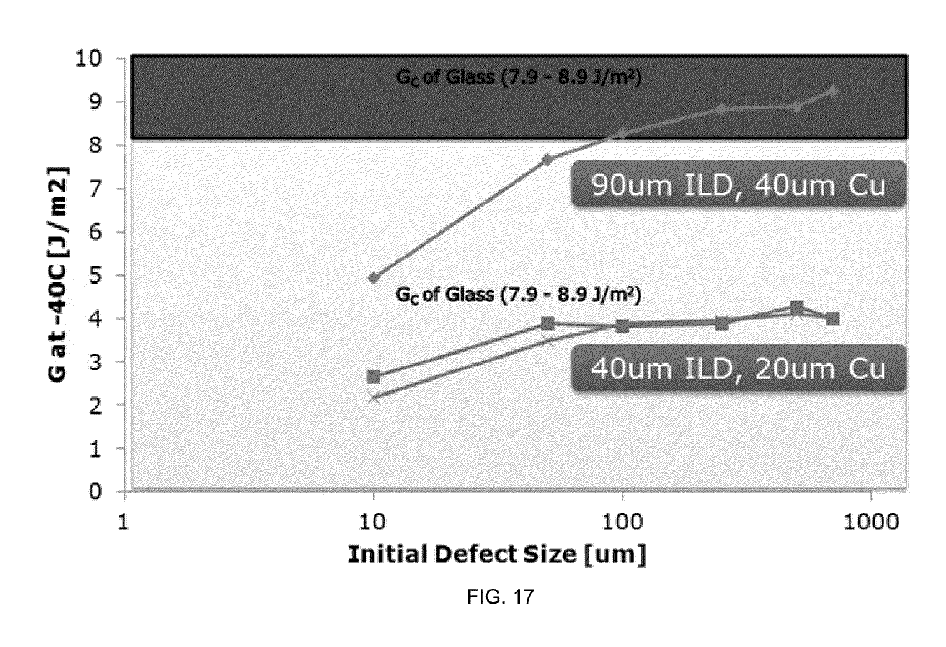

FIG. 17 shows a chart which displays that an redistribution layer (RDL) stack is a significant factor in design for safety. The chart shows a plot of the energy release rate required to grow cracks vs. the defect size. Reducing the RDL thickness can be effective in preventing crack growth for even large defect sizes.

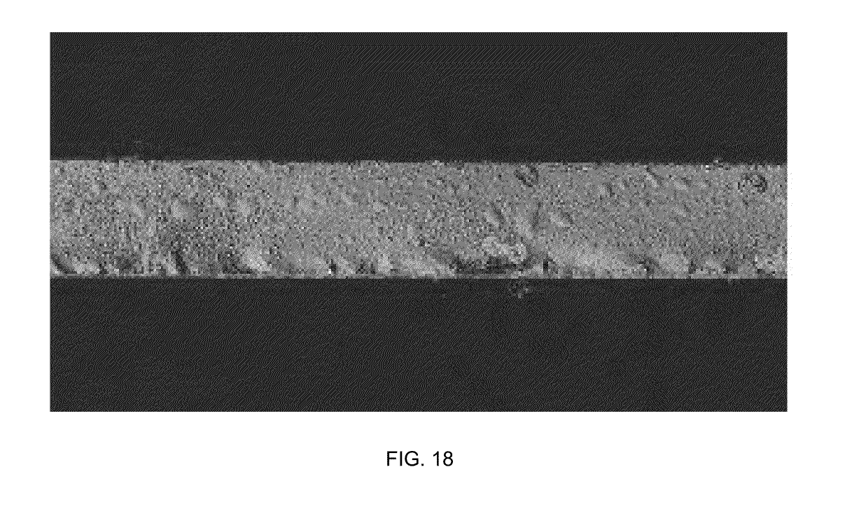

As previously described, the process of dicing glass panels may result in defects in the glass. FIG. 18 shows an example of a glass panel having defects resulting from the dicing process.

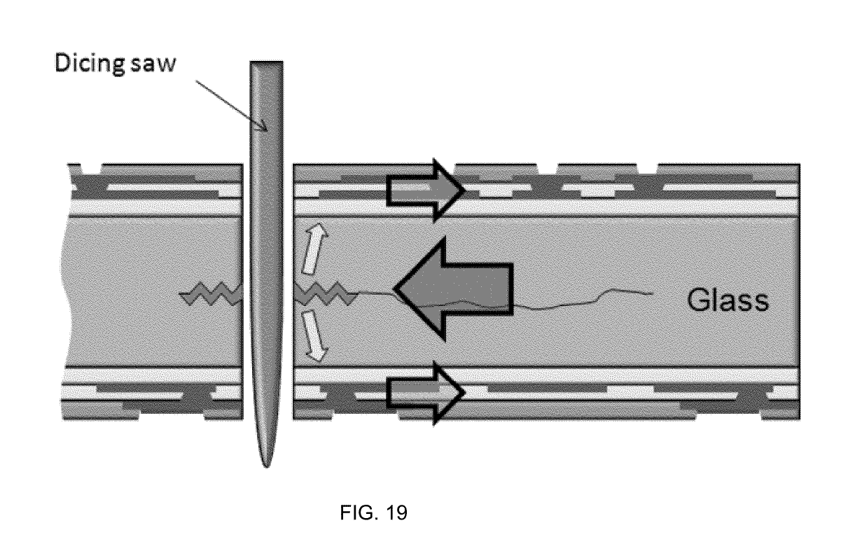

FIG. 19 shows an example illustration of cracking in the glass that may occurring due to the dicing process. Internal stress can accumulate in the glass due to the build-up process. The dicing process can create micro-cracks at glass etch. Then, a horizontal crack can propagate from the micro-cracks.

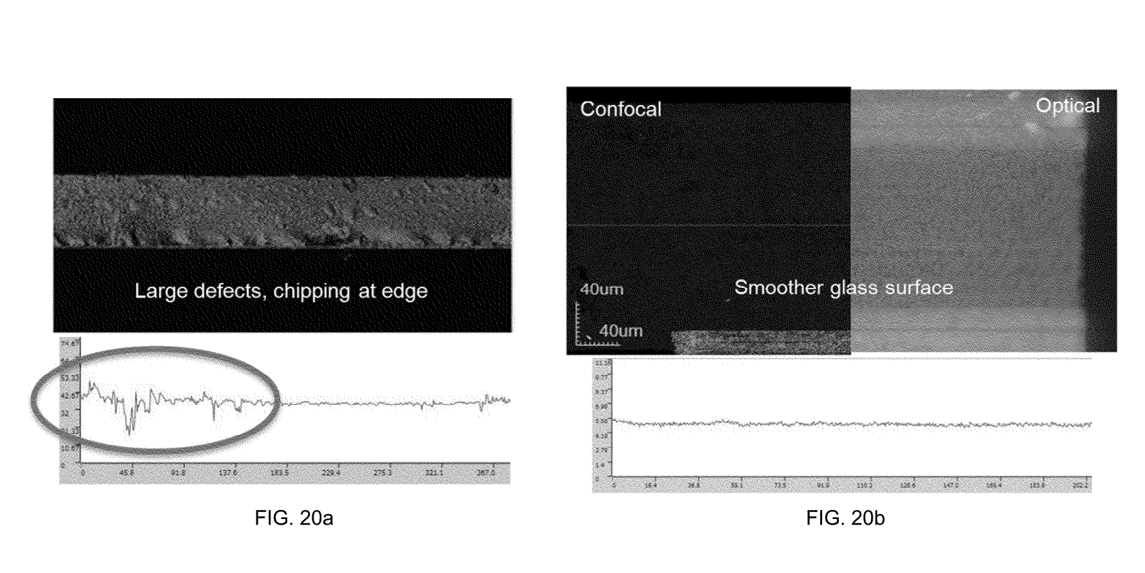

FIGS. 20a-b shows images where confocal microscopy is used to characterize surfaces of dicing methods. FIG. 20a-b show blade-diced surfaces.

Coating the edges of the microelectronic package is a new, more systematic approach to preventing the development of SeWaRe failures from unavoidable micro-defects present in the structure, such as those caused by dicing. The coated microelectronic packages described herein can, in some embodiments, can address the technical challenges by coating the exposed edges of the package with a coating (which can comprise a polymer). This technology can include applying a layer of coating material on all exposed edges of glass panels, interposers or packages.

The coating added to the exposed edges of the microelectronic package can include any material that can reduce additional cracking or propagation of defects in the package. In some embodiments, the coating has ideal flowability, viscosity and particles size to fill all defects, even sub-micron size cracks, in the package. In some embodiments, the coating is curable. In some embodiments, the curable coating has ideal curing properties (e.g., shrinkage upon curing) to reduce defects sizes and stress concentration by polymer shrinkage. In some embodiments, the polymer has ideal mechanical properties (e.g., low modulus, low glass transition point, and low coefficient of thermal expansion) to considerably slow crack propagation. Any material that would seal the edge and reduce crack propagation can be used in the coating.

In some embodiments, the coating includes a polymer. In some embodiments, the coating includes any polymer or combination of polymers as described herein for use in the stress relief barrier. In some embodiments, the coating includes a polyepoxide. In some embodiments, the polyepoxide has at least two 1,2-epoxy groups per molecule. The polyepoxides can, in some embodiments, be saturated, unsaturated, cyclic or acyclic, aliphatic, alicyclic, aromatic or heterocyclic polyepoxy compounds. Examples of polyepoxides include, but are not limited to, the polyglycidyl ethers obtained by reacting epichlorohydrin or epibromohydrin with a polyphenol in the presence of alkali. Polyphenols suitable for this purpose are, for example, resorcinol, pyrocatechol, hydroquinone, bisphenol A (bis(4-hydroxyphenyl)-2,2-propane)), bisphenol F(bis(4-hydroxyphenyl)methane), bis(4-hydroxyphenyl)-1,1-isobutane, 4,4′-dihydroxybenzophenone, bis(4-hydroxyphenyl)-1,1-ethane, 1,5-hydroxynaphthalene.

Further polyepoxides include, but are not limited to, the polyglycidyl ethers of polyalcohols or diamines. These polyglycidyl ethers are derives from polyalcohols, such as ethylene glycol, diethylene glycol, triethylene glycol, 1,2-propylene glycol, 1,4-butylene glycol, triethylene glycol, 1,5-pentanediol, 1,6-hexanediol or trimethylolpropane. Further polyepoxides include, but are not limited to, polyglycidyl esters of polycarboxylic acids, for example reaction products of glycidol or epichlorohydrin with aliphatic or aromatic polycarboxylic acids, such as oxalic acid, succinic acid, glutaric acid, terephthalic acid or dimer fatty acid. Further epoxides include, but are not limited to, those derived from the epoxidation products of olefinically unsaturated cycloaliphatic compounds or from natural oils and fats.

Polyepoxides derived from the reaction of bisphenol A or bisphenol F and epichlorohydrin can be used, in some embodiments. Mixtures of liquid and solid epoxy can be used. Liquid epoxy resins based on bisphenol A can be used. In some embodiments, the polyepoxide has a mean epoxide functionality of from 1 to 10 (e.g., 1 or greater, 2 or greater, 3 or greater, 4 or greater, 5 or greater, 6 or greater, 7 or greater, 8 or greater, 9 or greater, 1 or less, 2 or less, 3 or less, 4 or less, 5 or less, 6 or less, 7 or less, 8 or less, or 9 or less).

In some embodiments, the microelectronic package has one or more edges (e.g., 2 edges, 3 edges, 4 edges). In some embodiments, the coating covers all of the exposed edges of the microelectronic package. In some embodiments, the coating covers substantially all of the exposed edges of the microelectronic package (e.g., 95% or more, 98% or more, 99% or more, or 99.5% or more). In some embodiments, the coating covers only a portion of the exposed edges of the microelectronic package (e.g., a top portion of the edge, a bottom portion of the edge, or both). In other words, in some embodiments the edge is not coated fully but only a portion of the edge is covered by polymer (the upper and lower sections of the edges), because there are methods that may only coat the edges near the top and bottom but not the middle of the edge. In some embodiments, the coating covers a portion of the top of the microelectronic package. In some embodiments, the coating covers a portion of the bottom of the microelectronic package. In some embodiments, the coating covers all or substantially all of the top, the bottom, and the exposed edges of the microelectronic package. In some embodiments, the coating has an average thickness of from 0.1 microns to 200 microns. In some embodiments, the coating has an average thickness of 0.2 microns or greater (e.g., 0.5 microns or greater, 1 micron or greater, 2 microns or greater, 3 microns or greater, 4 microns or greater, 5 microns or greater, 6 microns or greater, 7 microns or greater, 8 microns or greater, 9 microns or greater, 10 microns or greater, 25 microns or greater, 50 microns or greater, 75 microns or greater, 100 microns or greater, 125 microns or greater, 150 microns or greater, or 175 microns or greater). In some embodiments, the coating has an average thickness of 10 microns or less (e.g., 0.5 microns or less, 1 micron or less, 2 microns or less, 3 microns or less, 4 microns or less, 5 microns or less, 6 microns or less, 7 microns or less, 8 microns or less, 9 microns or less, 10 microns or less, 25 microns or less, 50 microns or less, 75 microns or less, 100 microns or less, 125 microns or less, 150 microns or less, or 175 microns or less). In some embodiments, the coating is uniform.

In some embodiments, the coating further comprises a polyfunctional amine, acid anhydride, phenol, alcohol, thiol, or combination thereof. In some embodiments, the coating comprises an additive (e.g., pigment, filler, hardener, dispersing additive). In some embodiments, the coating is substantially free of fillers.

In some embodiments, the polymer has a viscosity of 180,000 centipoises or less (e.g., 160,000 centipoises or less, 140,000 centipoises or less, 120,000 centipoises or less, 100,000 centipoises or less, 90,000 centipoises or less, 80,000 centipoises or less, 60,000 centipoises or less, 40,000 centipoises or less, 20,000 centipoises or less, 10,000 centipoises or less, 5,000 centipoises or less, 1,000 centipoises or less, or 500 centipoises or less) at 25° C. In some embodiments, the polymer has a weight average molecular weight of 400 or less (e.g., 350 or less, 300 or less, 250 or less, 200 or less, or 100 or less). In some embodiments, the polymer has a Young's modulus of 35 GN/m² or less (e.g., 30 or less, 25 or less, 20 or less, 15 or less, 10 or less, or 5 or less) at 25° C. In some embodiments, the polymer has a coefficient of thermal expansion of 70 10⁻⁶ m/(m*K) or less at 25° C. These ranges are non-limiting. Any polymer or non-polymer coating material that can halt defect propagation can be used.

The coating can be applied to the microelectronic package using any coating method known in the art. The coating can be dispensed by classic underfilling dispense methods, dipping or overmolding to, for instance, coat exposed edges of the glass in a few microns thin layer. In some embodiments for trial testing, the polymer is coated on collar material on the side of the interposer (spread thin layer on FR4 board and dip the side of the interposer), dried at, for instance 70° C. (e.g., with a hot plate); the interposer can then be cleaned on the back side using for instance acetone and a wipe, and then subject to reflow. The coating material, in some embodiments, does not contain any filler and can have a low enough viscosity to flow and fill all surface defects, even micron-size ones. Shrinkage during curing of the polymer introduces compressive stress in the structure to reduce the width of micro-cracks, and thus, in some embodiments, the shrinking of the coating during drying or curing can be minimized. After curing, the polymer can act as a stress buffer, reducing stress concentration on the singularity points where the defects were previously located, thus eliminating the risk of SeWaRe failure during post-process steps such as chip-level and board-level assembly.

Also disclosed herein are methods of making an edge-coated microelectronic package, comprising providing a microelectronic package comprising a glass substrate, wherein the microelectronic package has a top, a bottom, and an exposed edge; and coating at least a portion of the top, at least a portion of the bottom, and substantially all of the exposed edge of the microelectronic package with a coating comprising a polymer. The coating can be a curable coating. Curing can be done by any method or combination of methods known in the art (e.g., UV curing, thermosetting, laser curing, etc.). In some embodiments, the coating does not need to be cured. As used herein, “edge” is not intended to include the sidewalls of a via.

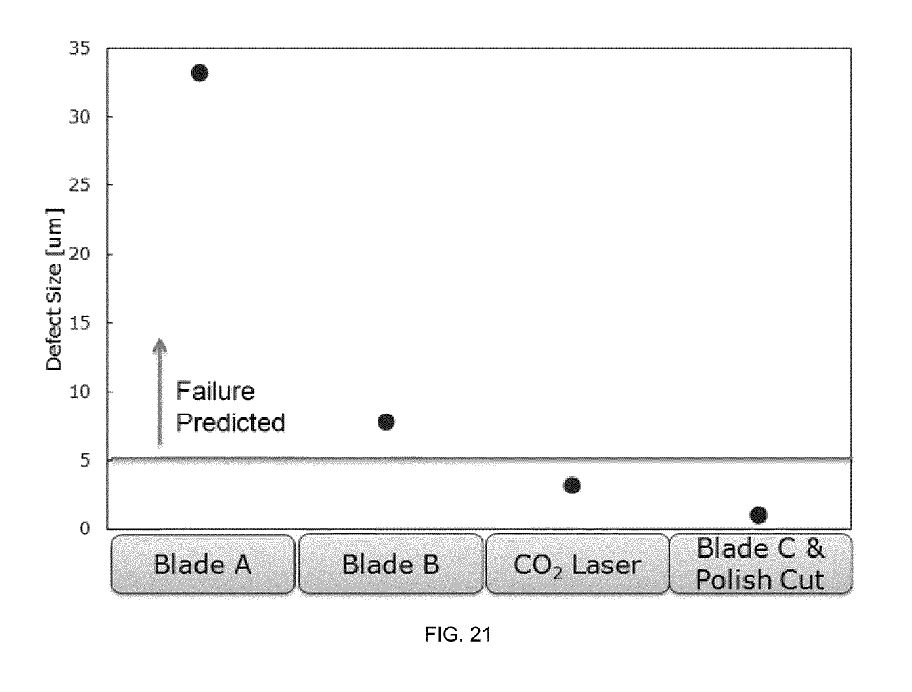

The edge-coated microelectronic package have improved properties. For instance, FIG. 21 shows a chart illustrating a dramatic improvement in dicing defect size reduction from Blade A, to Blade B, to CO₂ laser, and finally to Blade C and polish cut.

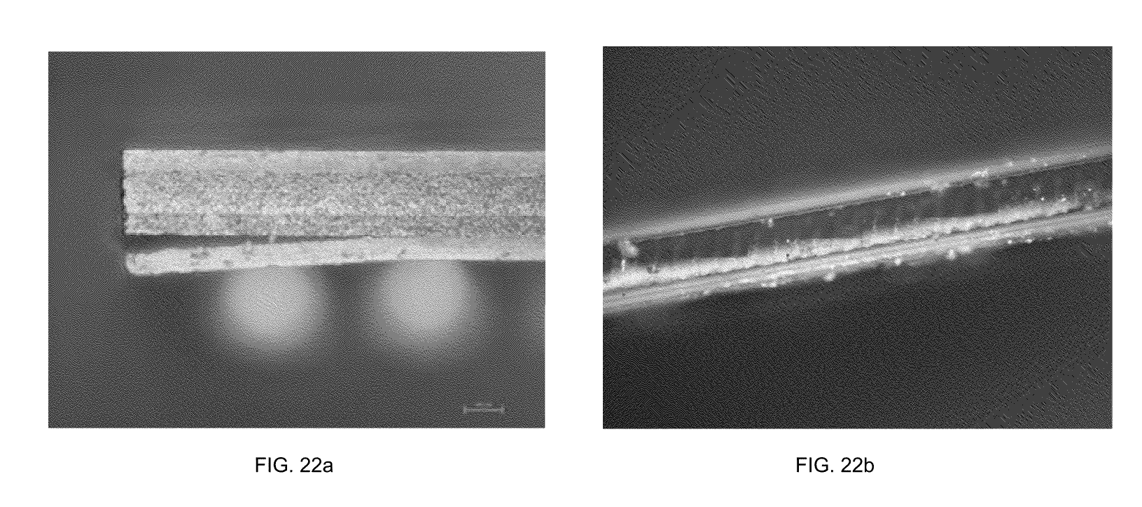

FIGS. 22a shows an edge with no treatment, compared to an edge with treatment shown in FIG. 22b. Post-dicing edge treatment can blunt defects and/or protect the edge to eliminate crack growth. Furthermore, post-dicing edge treatment can also stop or slow propogation of defects during thermal cycle testing (TCT). According to some embodiments, an edge can pass a moisture sensitivity level testing (MSL-3) and 1000 temperature cycles (−55 C,° to) 125 C.°. MSL-3 testing can be used to test for defects and failure. MSL-3 testing involves (1) preconditioning to emulate storage (e.g., wherein the package is created and left alone to absorb moisture); (2) reflow to simulate assembly (e.g., wherein the package is put on the motherboard to test the stress occurring in that stage; and (3) thermal cycle testing to simulate real-world use wherein the ultimate device may be subject to a variety of different climate/temperature conditions during the course of normal use. The MSL-3 reliability testing follows JEDEC standards (e.g., pre-conditioning: bake, MSL-3 (60° C., 60% RH, 40 h), 3 additional reflows at 260° C. peak temperature, and HAST & TCT).

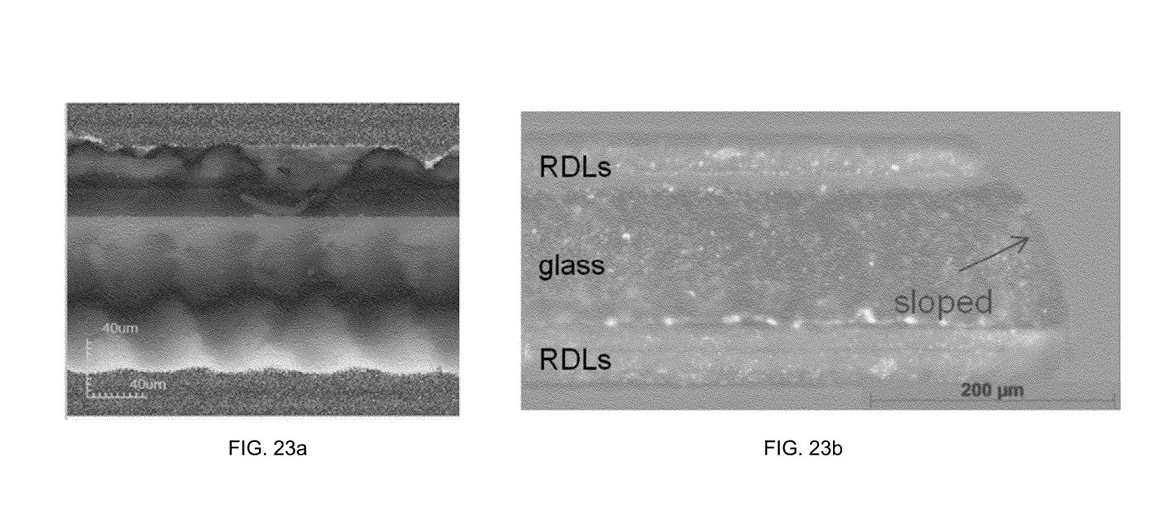

Laser dicing shows promising reliability. There can be multiple laser dicing methods, such as, CO₂ laser, pulsed laser, or laser break. FIG. 23a shows an example of a confocal microscopy of ablation edge. FIG. 23b shows an optical microscope observation. 100% of samples with and without edge protection passed 500 cycles (−55° C. to 125° C.).

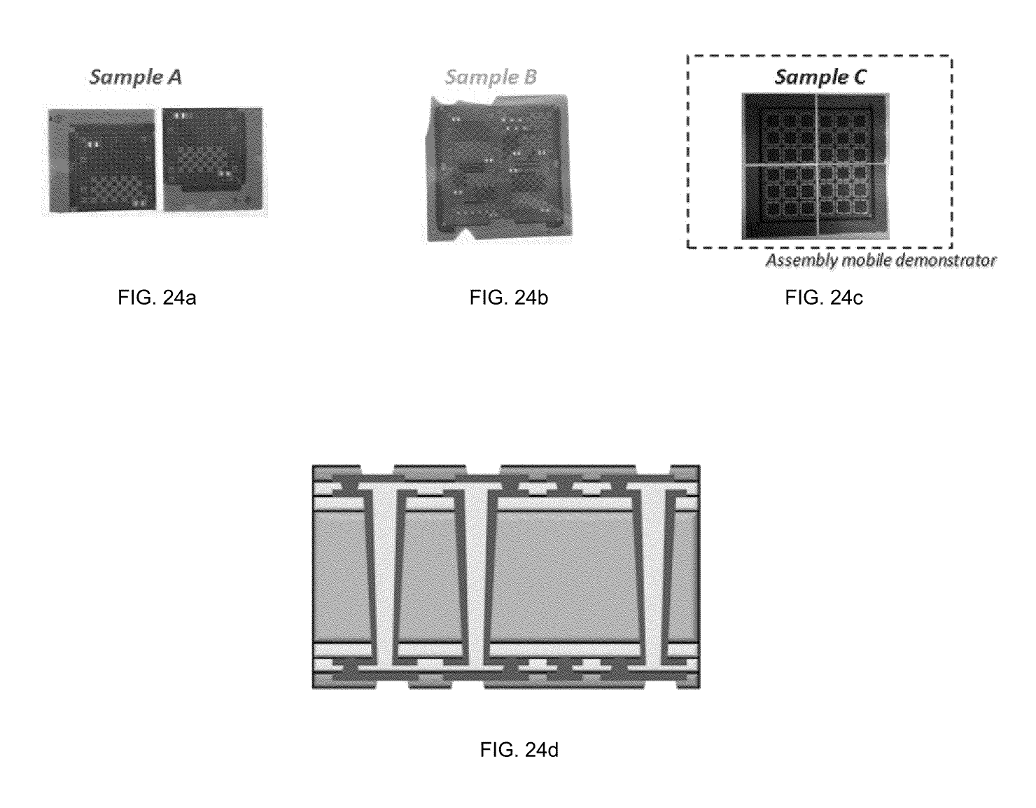

FIGS. 24a-c show pictures of samples for dicing evaluation by Disco. Glass cracking was observed on all of these structures after dicing was performed by different companies. Samples A and B were selected to have the same design. FIG. 24d shows a stack-up of the samples. Samples A and B have the following layers: Solder resist of 15 μm, 2^{nd} BU of 17.5 μm, 1^{st} BU of 17.5 μm, glass of 100 μm (TPVs in glass), 1^{st} BU 17.5 μm, 2^{nd} BU of 17.5 μm, and solder resist of 15 μm for a total size of about 200 μm. Sample C has the following layers: solder resist of 10 μm, 2^{nd} BU of 22.5 μm, 1^{st} BU of 22.5 μm, glass of 100 μm (no TPV), 1^{st} BU of 22.5 μm, 2^{nd} BU of 22.5 μm, and solder resist of 10 μm, for a total size of about 210 μm. The copper trace thickness is about 10 μm.

Table 2 below shows mobile demonstrator (sample C) diced with two different conditions (wherein C-1, 3, and 4 have a dicing speed of 1 mm/s and C-2 has a dicing speed of 2 mm/s).

| | | | | | | | | Wear | |
|---|---|---|---|---|---|---|---|---|---|
| | | | | | Spindle | Feed | | amount | |
| | Evaluation | | | | RPM | speed | | per sample | # of |
| Test | item | Sample | Index size | Blade | (min⁻¹) | (mm/s) | Cut method | (um) | SeWaRe |
| #1 | Same process | C-1 | 18.4 × 18.4 | R07-SD800-BB200-50 | 20,000 | 1 | 1 pass cut | 2 | 0 |
| #2 | as previous | B-2 | 3.6 × 3.6 | 52 × 0.1A2 × 40 | | | | 6 | 0 |
| | test | | | | | | | | |
| #3 | Feed speed | B-3 | 3.6 × 3.6 | | | 2 | | 7 | 1 |
| #4 | | C-2 | 18.4 × 18.4 | | | | | 2 | 0 |
| #5 | | A-1 | 3.6 × 3.6 | | | | | 9 | 0 |
| #6 | Cut method | B-4 | 3.6 × 3.6 | | | 4 | CH1&2 Half cut | 12 | 1 |
| | | | | | | | ->CH3&4 Full | | |
| | | | | | | | cut | | |
| #7 | With the best | C-3 | 18.4 × 18.4 | | | 1 | 1 pass cut | 0 | 0 |
| #8 | parameters | B-1 | 4.4 × 4.4 | | | | | 5 | 1 |
| #9 | | A-2 | 3.6 × 3.6 | | | | | 5 | 0 |
| #10 | | C-4 | 18.4 × 18.4 | | | | | 1 | 0 |

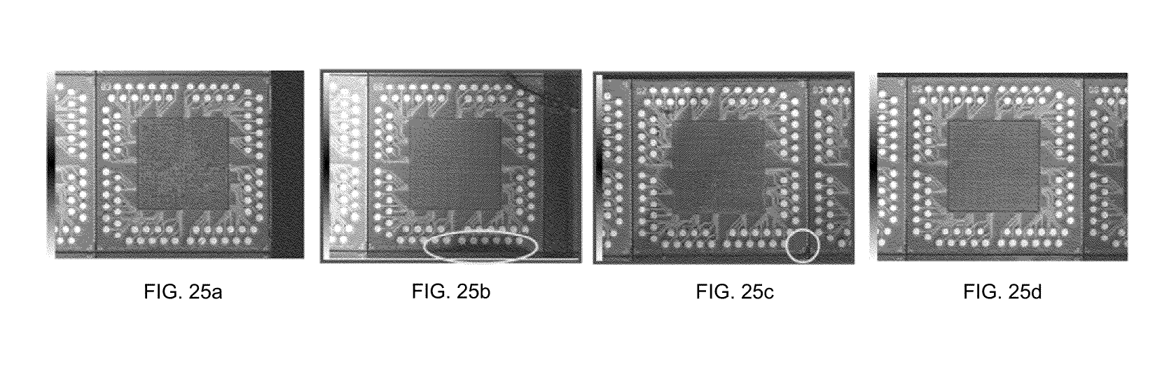

FIGS. 25a-d show a systematic C-SAM observation of all diced coupons of sample C according to dicing conditions C-1 through C-4. FIG. 25a shows C-1, FIG. 25b shows C-2, FIG. 25c shows C-3, and FIG. 25d shows C-4. The dicing speed of C-1, C-2, and C-4 was 1 mm/s, and the dicing speed of C-2 was 2 mm/s. The number of coupons with defects was reduced compared to first (non-optimized) dicing turn (by Disco & ADP). The optimization of the dicing process is highly beneficial to reduce surface defects on exposed glass edges. Cracks were observed in two dicing conditions—C-2 and C-3. Sample C-3 has minor defects. A slower dicing speed may be preferable but it has an impact on dicing throughput.

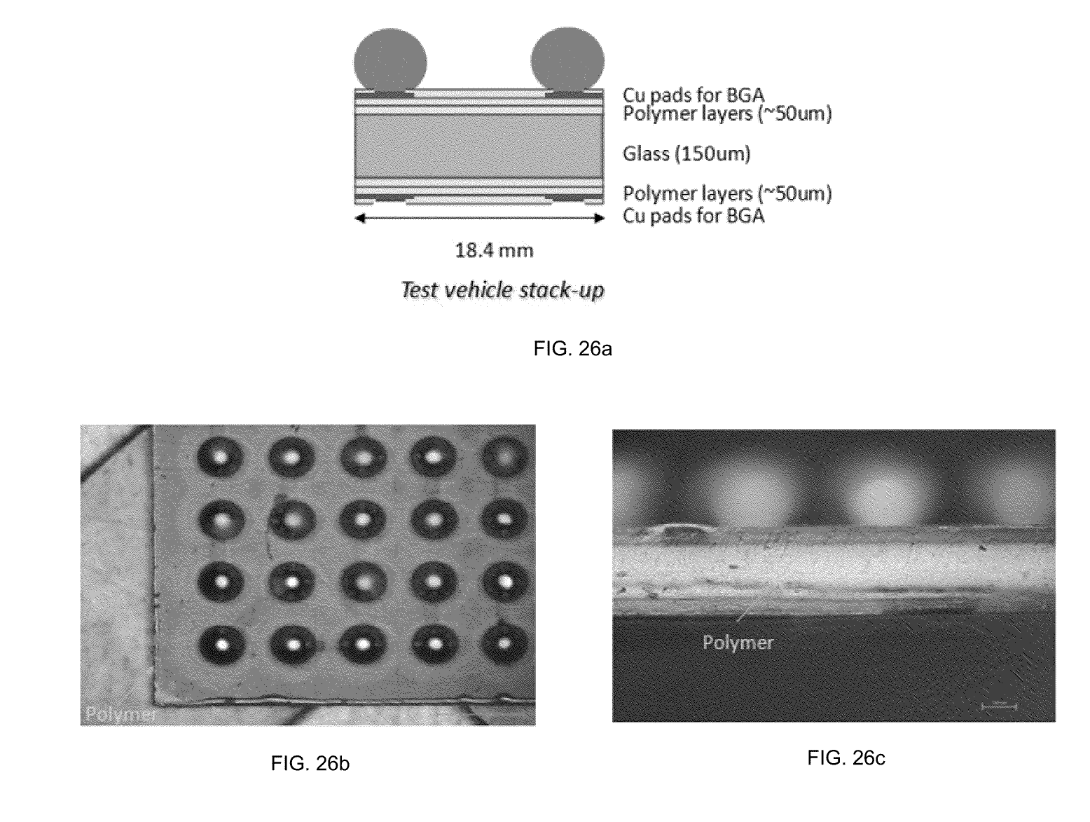

FIG. 26a shows a test vehicle stack up for a preliminary trial of glass edge coating. The test vehicle stack-up included no metal pattern on inner layers, identical metal patterns on both sides, 120 um BGA balls at 400 um pitch, and ZIF used as passivation. Exposed glass edges were coated by a thin layer of polymer to protect them. The test vehicle included 18.4 mm BLIAR SLI samples with and without visible SeWaRe after singulation. The material for edge coating trials was liquid epoxy-based polymer without filler, with good flowability to fill micro surface defects. The preliminary trials were based on successive reflows with 260 C.° peak temperature and C-SAM analysis. The trial included a reference sample with initial edge defects was not treated and a trial sample with edge coating. The edge coating procedure included polymer dispense on exposed glass edges in a thin uniform layer and curing of polymer material. FIGS. 26b and 26c show a top view and a side view, respectively. Slight contamination was observed on the ball side due to non-optimized dispense conditions.

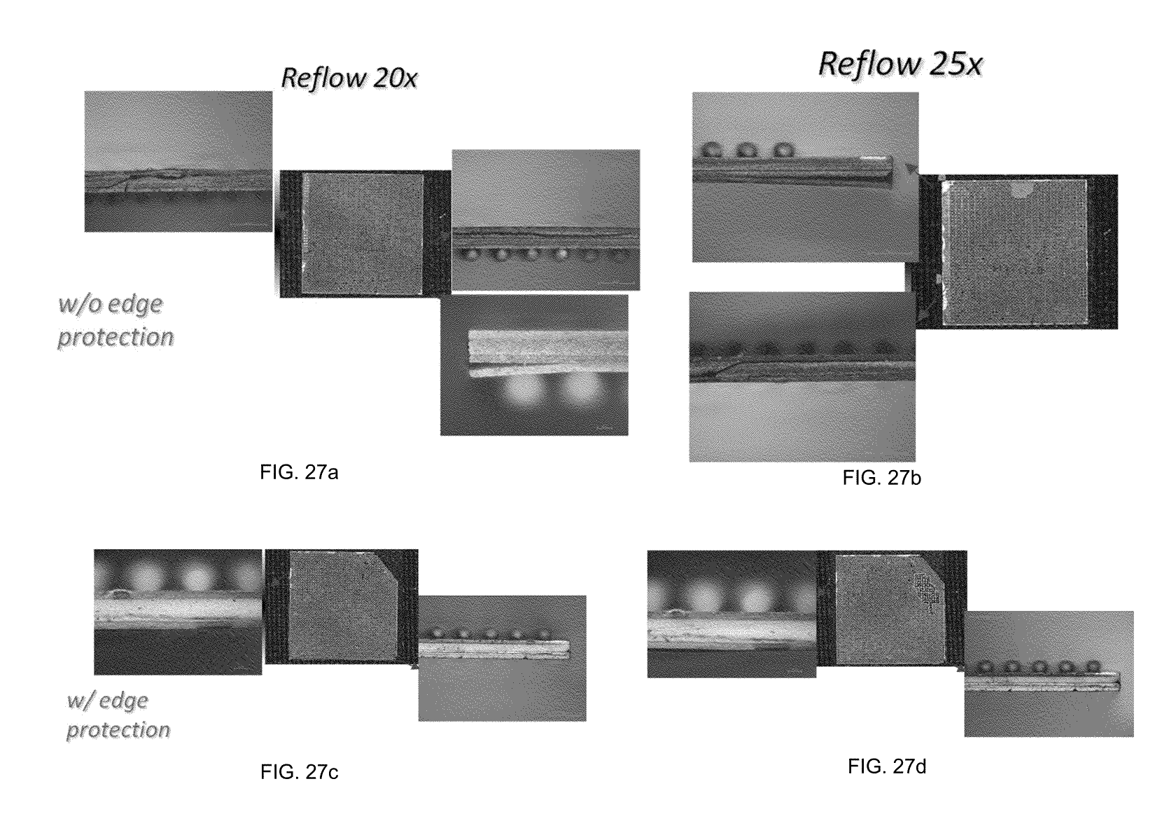

FIGS. 27a-d show side image views of edge coating trials. FIGS. 27a and 27b show edges without edge protection, whereas FIGS. 27c and 27d show edges with edge protection. FIGS. 27a and 27c show edges that have undergone reflow 20 times, whereas FIGS. 27b and 27d show edges that have undergone reflow 25 times. As can be seen in the examples of edges with edge protection, there is no evolution of originally present defects.

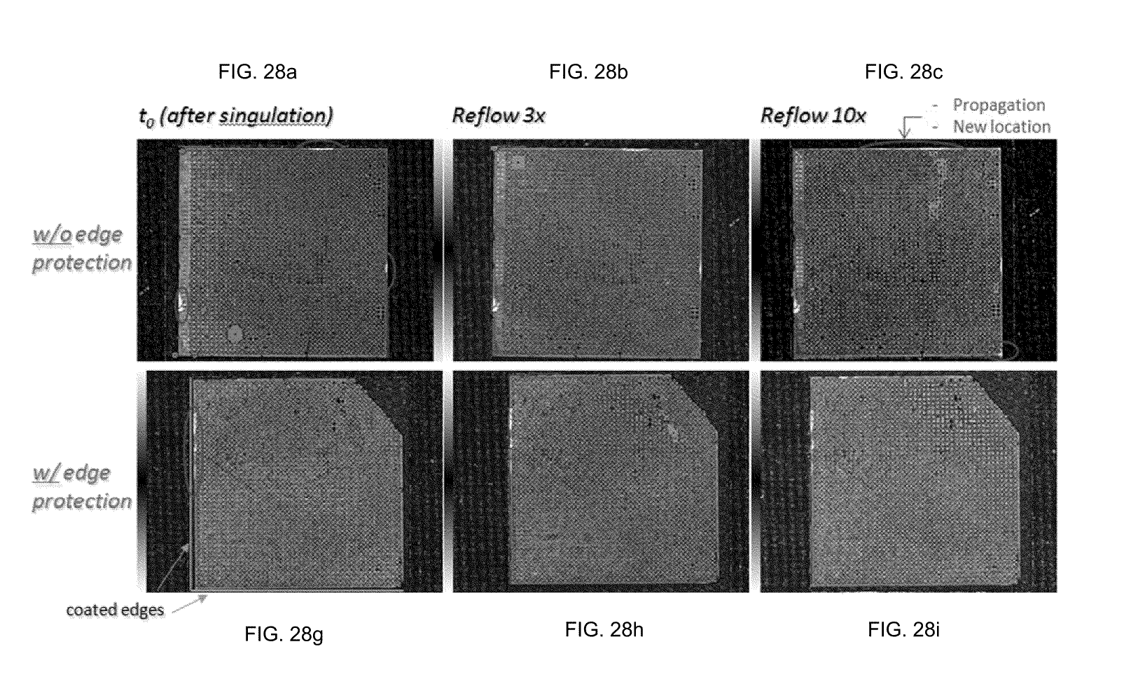

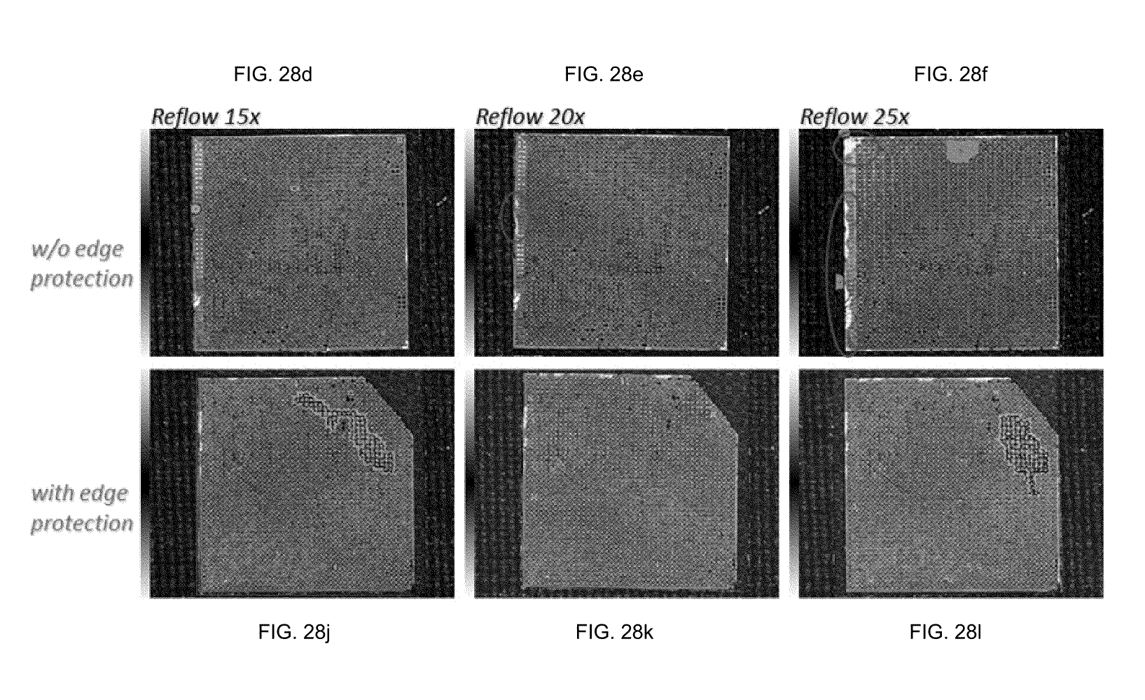

FIGS. 28a-l show a CSAM evaluation post reflow. FIGS. 28a-f show images of edges without edge protection, and FIGS. 28g-l show edges with edge protection. Images of each were taken at tₒ (after singulation), reflow 3×, reflow 10×, reflow 15×, reflow 20× and reflow 25×. Crack propagation and new failure locations were observed in edges without edge coating. No propagation of existing defects was observed in edges with edge coating. No failure was observed in edges that were originally “healthy” after edge coating.

The coated microelectronics packages and methods disclosed herein can be used in a variety of commercial applications. For instance, glass as a package and interposer can be used in a variety of mobile and high-performance systems. This technology can benefit glass manufacturers, supply chain and end users in all microsystems applications. Additionally, high volume manufacturing for displays and other applications is also possible.

The coated microelectronics packages and methods disclosed herein can have a variety of advantages. For instance, exposed glass edges are a reliability concern due to glass cracking after dicing (SeWaRe failure). This packages and methods disclosed herein can provide a low-cost manufacturable structure that protects glass edges and prevents this failure mechanism during processing steps and in operation.

While certain embodiments of the disclosed technology have been described in connection with what is presently considered to be the most practical embodiments, it is to be understood that the disclosed technology is not to be limited to the disclosed embodiments, but on the contrary, is intended to cover various modifications and equivalent arrangements included within the scope of the appended claims. Although specific terms are employed herein, they are used in a generic and descriptive sense only and not for purposes of limitation.

This written description uses examples to disclose certain embodiments of the disclosed technology, including the best mode, and also to enable any person skilled in the art to practice certain embodiments of the disclosed technology, including making and using any devices or systems and performing any incorporated methods. The patentable scope of certain embodiments of the disclosed technology is defined in the claims, and can include other examples that occur to those skilled in the art. Such other examples are intended to be within the scope of the claims if they have structural elements that do not differ from the literal language of the claims, or if they include equivalent structural elements with insubstantial differences from the literal language of the claims.

What is claimed is:

1. coated microelectronic package comprising:
a microelectronic package having a top, a bottom, and an exposed edge; and
a coating comprising a polymer,
wherein the microelectronic package comprises a glass substrate; and
wherein the coating covers at least a portion of the top, at least a portion of the bottom, and at least a portion of the exposed edge of the microelectronic package.

2. The apparatus of claim 1, wherein the microelectronic package further comprises:
a metalized or filled through substrate via;
a dielectric layer;
a stress relief barrier layer;
a metallization seed layer;
a passivation layer;
a conductor;
a blind via connecting any two conductor layers on either side of the glass substrate;
or a combination thereof.

3. The edge-coated microelectronic package of claim 2, wherein the glass substrate has a thickness of from 30 microns to 500 microns.

4. The edge-coated microelectronic package of claim 2, wherein the coating covers substantially all of the exposed edge of the microelectronic package.

5. The edge-coated microelectronic package of claim 2, wherein the coating has an average thickness of from 1 microns to 25 microns.

6. The edge-coated microelectronic package of claim 2, wherein the coating comprises epoxy, siloxane, benzocyclobutene, polyimide, polyenzoxazole, silicone, cyanate ester, polyolefin, hydrocarbons, polyurethanes, cyanoacrylates, or a combination thereof.

7. The edge-coated microelectronic package of claim 2, wherein the coating comprises a polyepoxide.

8. The edge-coated microelectronic package of claim 7, wherein the coating further comprises a polyfunctional amine, acid anhydride, phenol, alcohol, thiol, or combination thereof.

9. The edge-coated microelectronic package of claim 7, wherein the polyepoxide has a mean epoxide functionality of from 1 to 10.

10. The edge-coated microelectronic package of claim 2, wherein the polymer has a viscosity of 180,000 centipoises or less at 25° C.

11. The edge-coated microelectronic package of claim 2, wherein the polymer has a weight average molecular weight of 400 or less.

12. The edge-coated microelectronic package of claim 2, wherein the polymer has a Young's modulus of 35 GN/m² or less at 25° C.

13. The edge-coated microelectronic package of claim 2, wherein the polymer has a coefficient of thermal expansion of 70×10⁻⁶ m/(m*K) or less at 25° C.

14. The edge-coated microelectronic package of claim 6, wherein the polymer is substantially free of fillers.

15. A method of edge-coating a microelectronic package, the method comprising:
providing a microelectronic package comprising a glass substrate, wherein the microelectronic package has a top, a bottom, and an exposed edge; and
coating at least a portion of the top, at least a portion of the bottom, and a portion of the exposed edge of the microelectronic package with a coating comprising a polymer.

16. The method of claim 15, further comprising curing the coating.

17. The method of claim 15, wherein the curing comprises ultraviolet curing, laser curing, thermosetting, or a combination thereof.

18. The method of claim 15, wherein the coating covers substantially all of the exposed edge of the microelectronic package.

19. The method of claim 15, wherein the glass substrate has a thickness of from 30 microns to 500 microns.

20. The method of claim 15, wherein the coating comprises epoxy, siloxane, benzocyclobutene, polyimide, polyenzoxazole, silicone, cyanate ester, polyolefin, hydrocarbons, polyurethanes, cyanoacrylates, or a combination thereof.
